(19) United States
(12) Patent Application Publication
(10) Pub. No.: US 2025/0275364 A1
(43) Pub. Date: Aug. 28, 2025

(54) DISPLAY DEVICE, METHOD FOR FABRICATION THEREOF, AND HEAD MOUNTED DISPLAY DEVICE

(71) Applicant: Samsung Display Co., LTD., Yongin-si (KR)

(72) Inventors: Sin Chul KANG, Yongin-si (KR); Dae Ho SONG, Yongin-si (KR); Yo Han LEE, Yongin-si (KR); Sug Woo JUNG, Yongin-si (KR); Joo Sun CHOI, Yongin-si (KR)

(21) Appl. No.: 18/980,868

(22) Filed: Dec. 13, 2024

(30) Foreign Application Priority Data
Feb. 27, 2024 (KR) 10-2024-0028171

(51) Int. Cl. H10K 59/121; H10K 59/12; H10K 59/131

(52) U.S. Cl. CPC H10K 59/1213; H10K 59/1201; H10K 59/131

(57) ABSTRACT

A display device, a method for fabrication thereof, and a head mounted display device are provided. The display device includes a first single crystal semiconductor substrate at which first transistors are located, a second single crystal semiconductor substrate on the first single crystal semiconductor substrate, and at which second transistors are located, and a connection line layer between the first single crystal semiconductor substrate and the second single crystal semiconductor substrate. The second single crystal semiconductor substrate includes a display area where sub-pixels are located, each of the plurality of sub-pixels includes a light emitting element, a plurality of first through holes in a non-display area around the display area, and in which a first conductive via connected to data lines extending in a first direction is located, and a plurality of second through holes in the non-display area, and in which a second conductive via is located.

### CROSS-REFERENCE TO RELATED APPLICATION

The present application claims priority to and the benefit of Korean Patent Application No. 10-2024-0028171, filed on Feb. 27, 2024, in the Korean Intellectual Property Office, the entire disclosure of which is incorporated by reference herein.

### BACKGROUND

### 1. Field

One or more embodiments of the present disclosure relate to a display device, a method for fabrication thereof, and a head mounted display device.

### 2. Description of Related Art

A head mounted display device (HMD) is an image display device that is worn on a user's head in the form of glasses or helmets to form a focus at a close distance in front of the user's eyes. The head mounted display device may implement virtual reality (VR) and/or augmented reality (AR).

The head mounted display device magnifies an image displayed on a small display device by using a plurality of lenses, and displays the magnified image. Therefore, the display device applied to the head mounted display device needs to provide high-resolution images, for example, images with a resolution of 3000 Pixels Per Inch (PPI) or higher. To this end, an organic light emitting diode on silicon (OLEDoS), which is a high-resolution small organic light emitting display device, is used as the display device applied to the head mounted display device. The OLEDOS is an image display device in which an organic light emitting diode (OLED) is disposed on a semiconductor wafer substrate on which a complementary metal oxide semiconductor (CMOS) is disposed.

### SUMMARY

Aspects and features of embodiments of the present disclosure provide a display device including a plurality of different single crystal semiconductor substrates, and a head mounted display device including the same.

Aspects and features of embodiments of the present disclosure also provide a display device that is implemented by efficient disposition design of through holes connecting two different semiconductor substrates and a method for fabrication thereof.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a first single crystal semiconductor substrate at which a plurality of first transistors is located, a second single crystal semiconductor substrate on the first single crystal semiconductor substrate, and at which a plurality of second transistors is located, and a connection line layer between the first single crystal semiconductor substrate and the second single crystal semiconductor substrate. The second single crystal semiconductor substrate includes a display area where a plurality of sub-pixels is located, each of the plurality of sub-pixels comprising a light emitting element, a plurality of first through holes in a non-display area around the display area, and in which a first conductive via connected to a plurality of data lines extending in a first direction is located, and a plurality of second through holes in the non-display area, and in which a second conductive via connected to a plurality of first scan lines extending in a second direction is located. The connection line layer includes a first connection line connecting the first conductive via to a data driver on the first single crystal semiconductor substrate, and a second connection line connecting the second conductive via to a scan driver on the first single crystal semiconductor substrate.

The first through holes may be spaced from each other, and the second through holes may be spaced from each other.

The plurality of first through holes and the plurality of second through holes may be each spaced from the other adjacent first through holes or the other adjacent second through holes in a diagonal direction.

In the display area, a plurality of pixels including three sub-pixels may be arranged. Three first through holes may be in a region occupied by one pixel extending in one direction toward the non-display area.

The pixel may include three sub-pixel portions respectively corresponding to the plurality of sub-pixels. A distance between the first through holes may be 61.0328% or less of a distance between corresponding sub-pixel portions in neighboring pixels from among the plurality of pixels.

The plurality of first through holes and the plurality of second through holes may not overlap the first single crystal semiconductor substrate. Each of the first connection lines and the second connection lines may have at least a portion overlapping the first single crystal semiconductor substrate.

The second single crystal semiconductor substrate may be in the non-display area, and may include a plurality of third through holes in which a third conductive via connected to a plurality of second scan lines extending in the second direction is located, and the connection line layer may include a third connection line connecting the third conductive via to an emission driver on the first single crystal semiconductor substrate.

A number of the first through holes may be equal to a number of the data lines, and a number of pixel columns of the plurality of sub-pixels.

A number of the second through holes may be equal to a number of the first scan lines, and may be greater than a number of pixel rows of the plurality of sub-pixels.

The display device may further include a plurality of signal terminals on the first single crystal semiconductor substrate. The second single crystal semiconductor substrate may further include a plurality of fourth through holes formed in the non-display area. The connection line layer may further include a fourth connection line connecting the signal terminal to a fourth conductive via in the fourth through hole.

An area of the first single crystal semiconductor substrate in a plan view may be smaller than an area of the second single crystal semiconductor substrate in a plan view.

A length of a minimum line width of the first transistor may be smaller than a length of a minimum line width of the second transistor.

The minimum line width of the first transistor may be less than 100 nm. The minimum line width of the second transistor may be greater than or equal to 100 nm.

The display device further includes a passivation layer around the first single crystal semiconductor substrate and overlapping the second single crystal semiconductor substrate.

According to one or more embodiments of the present disclosure, there is provided a method for fabrication of a display device, including preparing a first wafer substrate and a second wafer substrate different from each other, forming a plurality of first transistors on the first wafer substrate, forming a pixel circuit on one surface of the second wafer substrate, and forming a plurality of through holes penetrating at least a part of the second wafer substrate and a plurality of conductive vias respectively in the plurality of through holes, forming a connection line layer including a plurality of connection lines on the other surface of the second wafer substrate, which is opposite to the one surface, dividing the first wafer substrate into a plurality of first single crystal semiconductor substrates, and locating the first single crystal semiconductor substrate on an other surface of the second wafer substrate, forming a planarization layer covering the one surface of the second wafer substrate and the first single crystal semiconductor substrates attached to the one surface, forming a display element layer including a plurality of light emitting elements on the other surface of the second wafer substrate, which is opposite to the one surface, and dividing the second wafer substrate into a plurality of second single crystal semiconductor substrates in which the display element layer is formed on the one surface and the first single crystal semiconductor substrate is on the other surface. The plurality of through holes include a plurality of first through holes in a non-display area around the display area and having a first conductive via therein, and a plurality of second through holes in the non-display area and having a second conductive via therein. The connection line layer includes a first connection line connecting the first conductive via and a data driver on the first single crystal semiconductor substrate, and a second connection line connecting the second conductive via to a scan driver on the first single crystal semiconductor substrate.

The method may further include performing etching to reduce a thickness of the second wafer substrate after the forming of the plurality of through holes and the plurality of conductive vias. The first single crystal semiconductor substrate may be attached to the connection line layer.

Each of the plurality of first through holes and the plurality of second through holes may not overlap the first single crystal semiconductor substrate.

An area of the first single crystal semiconductor substrate in a plan view may be smaller than an area of the second single crystal semiconductor substrate in a plan view.

In the forming of the pixel circuit on the second wafer substrate, a plurality of second transistors may be formed on the second wafer substrate. A length of a minimum line width of the first transistor may be smaller than a length of a minimum line width of the second transistor.

According to one or more embodiments of the present disclosure, there is provided a head mounted display device including a frame configured to be mounted on a user's body and corresponding to left and right eyes, a plurality of display devices in the frame, and a lens on each of the plurality of display devices. The display device includes a first single crystal semiconductor substrate at which a plurality of first transistors is located, a second single crystal semiconductor substrate on the first single crystal semiconductor substrate, and at which a plurality of second transistors is located, and a connection line layer between the first single crystal semiconductor substrate and the second single crystal semiconductor substrate. The second single crystal semiconductor substrate includes a display area where a plurality of sub-pixels is located, each of the plurality of sub-pixels including a light emitting element, a plurality of first through holes formed in a non-display area around the display area, and in which a first conductive via connected to a plurality of data lines extending in a first direction is located, and a plurality of second through holes formed in the non-display area, and in which a second conductive via connected to a plurality of first scan lines extending in a second direction is located. The connection line layer includes a first connection line connecting the first conductive via to a data driver on the first single crystal semiconductor substrate, and a second connection line connecting the second conductive via to a scan driver on the first single crystal semiconductor substrate.

The display device according to one or more embodiments may include two different single crystal semiconductor substrates and through holes through which routing lines connecting the two different single crystal semiconductor substrates are disposed. In the fabrication process of the single crystal semiconductor substrate disposed on the lower side, a large number of semiconductor substrates per unit wafer substrate can be fabricated, so that the fabrication yield may be improved.

### BRIEF DESCRIPTION OF THE DRAWINGS

The above and other embodiments and features of the present disclosure will become more apparent by describing embodiments thereof with reference to the attached drawings, in which:

FIG. 1 is an exploded perspective view of a display device according to one or more embodiments;

FIG. 2 is a plan view illustrating an example of the driving part shown in FIG. 1;

FIG. 3 is a plan view illustrating an example of the display part shown in FIG. 1;

FIG. 4 is a plan view showing the disposition of a plurality of wires disposed in the display part of FIG. 3;

FIG. 5 is a block diagram illustrating a display device according to one or more embodiments;

FIG. 6 is an equivalent circuit diagram of one pixel according to one or more embodiments;

FIG. 7 is a schematic cross-sectional view of a display device according to one or more embodiments;

FIG. 8 is a schematic diagram showing a rear surface of a display device according to one or more embodiments;

FIG. 9 is a schematic cross-sectional view of a driving part according to one or more embodiments;

FIG. 10 is a plan view showing a pixel defining film, and first electrodes and emission areas of a plurality of sub-pixels disposed in a display area of a display part according to one or more embodiments;

FIG. 11 is a plan view showing a pixel defining film, and first electrodes and emission areas of a plurality of sub-pixels disposed in a display area of a display part according to one or more embodiments;

FIGS. 12-14 are cross-sectional views showing a portion of a display area and a portion of a non-display area in a display part according to one or more embodiments;

FIG. 15 is a diagram illustrating the relative disposition of pixels and through holes disposed in a display part of a display device according to one or more embodiments;

FIG. 16 is a flowchart illustrating a method for fabrication of the display device according to one or more embodiments;

FIGS. 17-22 are diagrams sequentially showing a fabrication process of a display device according to one or more embodiments;

FIGS. 23-34 are cross-sectional views sequentially illustrating a fabrication process of a display device according to one or more embodiments;

FIG. 35 is a plan view illustrating the disposition of a plurality of wires disposed in a display part of a display device according to one or more embodiments;

FIG. 36 is a schematic diagram showing the rear surface of the display device of FIG. 35;

FIG. 37 is a diagram illustrating the relative disposition of through holes and pixels disposed in a display part of the display device of FIG. 35;

FIG. 38 is a perspective view illustrating a head mounted display device according to one or more embodiments;

FIG. 39 is an exploded perspective view showing an example of the head mounted display device of FIG. 38; and

FIG. 40 is a perspective view illustrating a head mounted display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

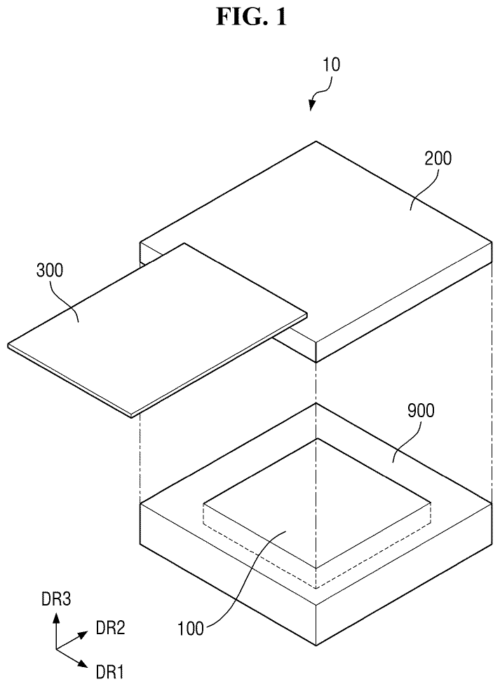

FIG. 1 is an exploded perspective view of a display device according to one or more embodiments.

Referring to FIG. 1, a display device 10 according to one or more embodiments is a device for displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 may be applied as a display part of a television, a laptop, a monitor, a billboard, and/or an Internet-of-Things (IoT) device. Alternatively, the display device 10 may be applied to a smart watch, a watch phone, a head mounted display device (HMD) for implementing virtual reality and augmented reality, and/or the like.

The display device 10 according to one or more embodiments may include a driving part 100, a display part 200, and a circuit board 300. The display device 10 may further include a passivation layer 900 disposed around the driving part 100.

The driving part 100 may have a planar shape similar to a quadrilateral shape. For example, the driving part 100 may have a planar shape similar to a rectangular shape, having one side of a first direction DR1 and the other side of a second direction DR2 crossing the first direction DR1. The one side of the driving part 100 in the first direction DR1 and the other side thereof in the second direction DR2 may have different lengths. In the driving part 100, a corner where one side in the first direction DR1 and the other side in the second direction DR2 meet may be right-angled or rounded with a suitable curvature (e.g., a predetermined curvature). The planar shape of the driving part 100 is not limited to a rectangular shape, and may be a shape similar to another polygonal shape, a circular shape, and/or an elliptical shape.

The display part 200 may be disposed on the driving part 100. In the display device 10, the driving part 100 and the display part 200 may be bonded to each other. Unlike the driving part 100, the display part 200 may have a shape similar to a square. For example, the driving part 100 and/or the display part 200 may have a planar shape similar to a square in which one side in the first direction DR1 and the other side in the second direction DR2 crossing the first direction DR1 have the same length. The planar shape of the display part 200 is not limited to a rectangular shape, and may be a shape similar to another polygonal shape, a circular shape, and/or an elliptical shape. The planar shape of the display device 10 may conform to the planar shape of the display part 200, but is not limited thereto.

According to one or more embodiments, in the display device 10, the area of the display part 200 in a plan view may be larger than the area of the driving part 100 in a plan view. The display device 10 may include the driving part 100 and the display part 200 having different substrates, and they may have different areas. Elements formed in the driving part 100 and elements formed in the display part 200 may be different, and these elements may be formed individually on different substrates. The display device 10 may be fabricated by forming multiple elements with different sizes, line widths, and fabrication processes on different substrates and then bonding them. Product performance and fabrication yield may be improved by manufacturing the display device 10.

The circuit board 300 may be electrically connected to a plurality of pads in a pad area of the display part 200 by using a conductive adhesive member such as an anisotropic conductive film. The circuit board 300 may be a flexible printed circuit board (FPCB) with a flexible material, and/or a flexible film. Although the circuit board 300 is illustrated in FIG. 1 as being unfolded, the circuit board 300 may be bent. In this case, one end of the circuit board 300 may be disposed on the bottom surface of the driving part 100. The other end of the circuit board 300 may be connected to the plurality of pads in the pad area of the display part 200 by using the conductive adhesive member. In one or more embodiments, the circuit board 300 may be attached to the bottom surface of the driving part 100.

The passivation layer 900 may be disposed on the bottom surface of the display part 200 while being around (e.g., surrounding) the driving part 100. The passivation layer 900 may reduce a level difference caused by the difference in area between the driving part 100 and the display part 200, and may also protect the driving part 100 and the display part 200.

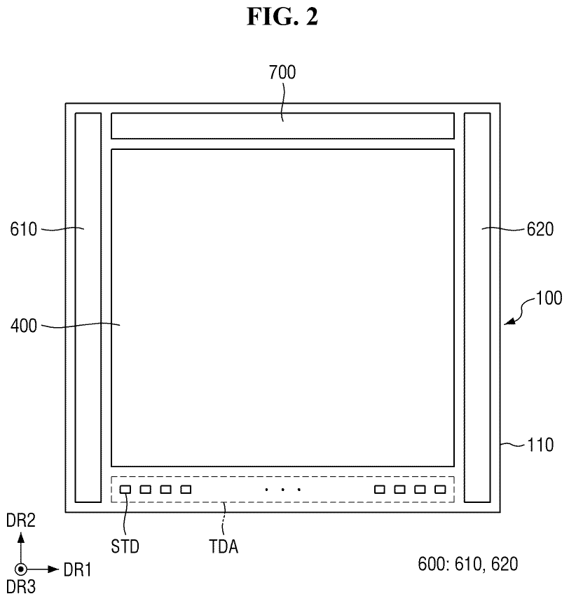

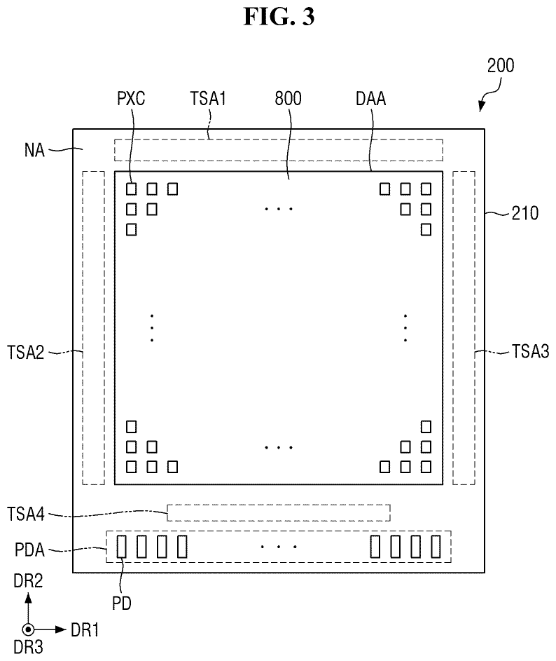

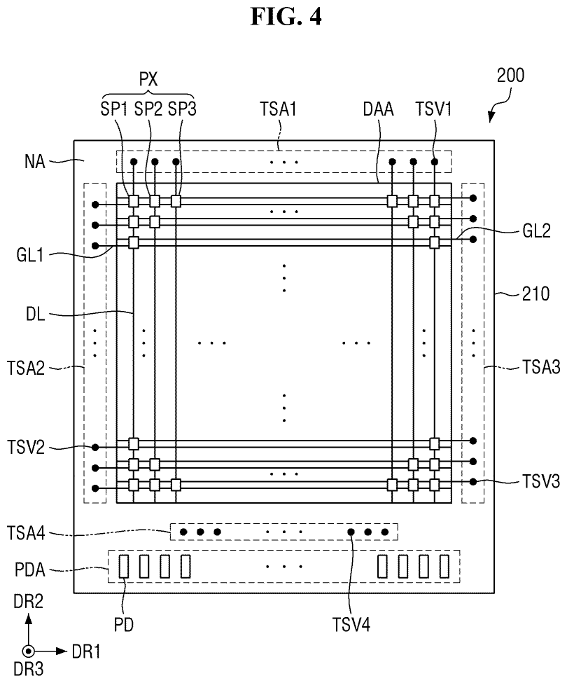

FIG. 2 is a plan view illustrating an example of the driving part shown in FIG. 1. FIG. 3 is a plan view illustrating an example of the display part shown in FIG. 1. FIG. 4 is a plan view showing the arrangement of a plurality of wires disposed in the display part of FIG. 3.

Referring to FIGS. 2-4, the driving part 100 of the display device 10 may include driving circuit elements of the display device 10. The driving part 100 may include a first single crystal semiconductor substrate 110, and a driving circuit 400, a gate driver 600, and a data driver 700 formed on the first single crystal semiconductor substrate 110. The gate driver 600 may include a scan driver 610 and an emission driver 620.

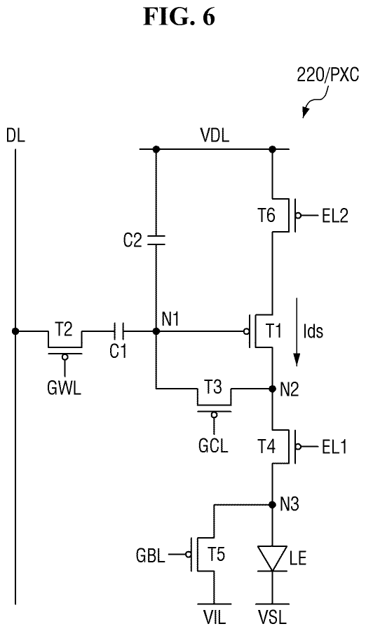

The first single crystal semiconductor substrate 110 may be a silicon substrate, a germanium substrate, or a silicon-germanium substrate. A plurality of first transistors may be formed on the first single crystal semiconductor substrate 110. The plurality of first transistors may be electrically connected to each other and may constitute the driving circuit 400, the gate driver 600:610 and 620, the data driver 700, and a pixel circuit 220 (e.g., PXC of FIG. 6). The first transistors may be formed through a semiconductor process. For example, the plurality of transistors may be formed as complementary metal oxide semiconductor (CMOS) transistors.

In FIG. 2, for example, it is illustrated that the driving circuit 400 is disposed at the center portion of the driving part 100, the data driver 700 and a signal terminal area TDA are disposed at the upper side and the lower side thereof of the driving circuit 400 in the second direction DR2, and the gate driver 600:610 and 620 is disposed to both sides of the driving circuit 400 in the first direction DR1. The scan driver 610 may be disposed to the left side of the driving circuit 400, and the emission driver 620 may be disposed to the right side of the driving circuit 400. However, the present disclosure is not limited thereto. The positions of the driving circuit 400, the gate driver 600:610 and 620, and the data driver 700 may be varied depending on the design structure of a plurality of circuit elements formed on the first single crystal semiconductor substrate 110.

In the signal terminal area TDA, a plurality of signal terminals STD arranged along the first direction DR1 may be disposed. The plurality of signal terminals STD may be electrically connected to the display part 200 and may be electrically connected to the circuit board 300 via them. The signal terminals STD may transmit an electrical signal applied from the circuit board 300 to the driving circuit 400, the gate driver 600, the data driver 700, and the pixel circuit 220 (e.g., PXC of FIG. 6).

The display part 200 may include a second single crystal semiconductor substrate 210, and a plurality of pixels PX and the pixel circuit 220 (e.g., PXC of FIG. 6) formed on the second single crystal semiconductor substrate 210. The display part 200 may include a display area DAA where the plurality of pixels PX are disposed and a non-display area NA around (e.g., surrounding) the display area DAA along an edge or a periphery of the display area DAA. Through hole areas TSA1, TSA2, TSA3, and TSA4 and a pad area PDA may be disposed in the non-display area NA.

The second single crystal semiconductor substrate 210 may be a silicon substrate, a germanium substrate, and/or a silicon-germanium substrate. A plurality of second transistors may be formed on the second single crystal semiconductor substrate 210, and the plurality of second transistors may be electrically connected to each other to form the pixel circuit 220 (e.g., PXC of FIG. 6) for light emission of the plurality of pixels PX. The second transistors may be formed through a semiconductor process. For example, the plurality of transistors may be formed as complementary metal oxide semiconductor (CMOS) transistors.

The plurality of pixels PX including light emitting elements may be disposed in the display area DAA. Each of the plurality of pixels PX may include three sub-pixels, for example, a first sub-pixel SP1, a second sub-pixel SP2, and a third sub-pixel SP3. Three sub-pixels SP1, SP2, and SP3 may constitute one pixel PX to display a color. However, the present disclosure is not limited thereto, and one pixel PX may include three or more sub-pixels. The plurality of sub-pixels SP may be arranged in a matrix form along the first direction DR1 and the second direction DR2. For example, the plurality of sub-pixels SP may be arranged along rows and columns of a matrix along the first direction DR1 and the second direction DR2. Each of the plurality of sub-pixels SP1, SP2, and SP3 may be electrically connected to a pixel circuit PXC (see FIG. 6) composed of the plurality of second transistors formed on the second single crystal semiconductor substrate 210. Each of the sub-pixels SP1, SP2, and SP3 may include light emitting elements, and the light emitting elements may emit light according to an electrical signal applied from a pixel circuit disposed in the display area DAA.

Some of the sub-pixels SP1, SP2, and SP3 disposed in the display area DAA of the display part 200 may overlap the driving part 100 in a thickness direction of the display device 10 (e.g., a third direction DR3), and others may not overlap the driving part 100. The driving part 100 has a smaller area than that of the display part 200 and may be disposed adjacent to one side of the display part 200. Accordingly, only some of the sub-pixels SP1, SP2, and SP3 may overlap the driving part 100 in the thickness direction (e.g., the third direction DR3).

The pixel circuit 220 (e.g., PXC of FIG. 6) includes a plurality of pixel transistors formed on the second single crystal semiconductor substrate 210. The plurality of pixel transistors may be formed through a semiconductor process. For example, the plurality of pixel transistors may be formed as CMOS transistors.

The pixel circuit 220 may include the pixel circuit PXC (e.g., see FIG. 6) composed of the plurality of pixel transistors and electrically connected to each of the sub-pixels SP1, SP2, and SP3, and a plurality of scan lines GL1 and GL2 and data lines DL. The plurality of pixel circuits PXC may be arranged along the first direction DR1 and the second direction DR2 in the pixel circuit 220. The arrangement of the pixel circuits PXC may be similar to the arrangement of the sub-pixels SP1, SP2, and SP3.

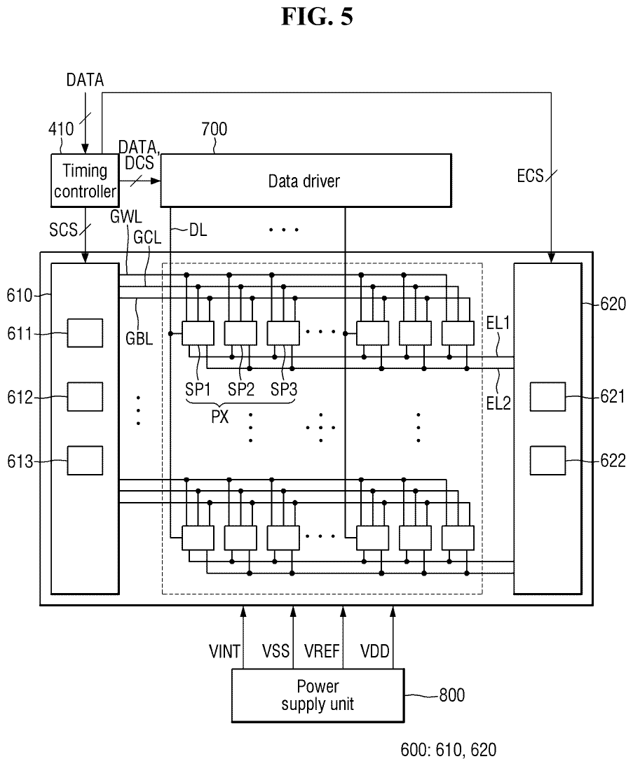

The plurality of scan lines GL1 and GL2 may extend in the first direction DR1 and may be spaced (e.g., spaced apart) from each other in the second direction DR2, and the plurality of data lines DL may extend in the second direction DR2 and may be spaced (e.g., spaced apart) from each other in the first direction DR1. The plurality of data lines DL may extend from a first through hole area TSA1 disposed to the upper side of the display area DAA, and the plurality of scan lines GL1 and GL2 may extend from a second through hole area TSA2 and a third through hole area TSA3 disposed to the left and right sides of the display area DAA, respectively. The plurality of scan lines GL1 and GL2 may include different types of scan lines, e.g., first to third scan lines GWL, GCL, and GBL (see FIG. 5) and emission control lines EL1 and EL2 (see FIG. 5). For example, first scan lines GL1 extending from the second through hole area TSA2 may include the first to third scan lines GWL, GCL, and GBL (see FIG. 5), and second scan lines GL2 extending from the third through hole area TSA3 may include the plurality of emission control lines EL1 and EL2 (see FIG. 5). The plurality of scan lines GL1 and GL2 and the data lines DL may be connected to the plurality of sub-pixels SP1, SP2, and SP3 of the display area DAA. The plurality of scan lines GL1 and GL2 may be electrically connected to the gate driver 610 and 620 of the driving part 100, and the plurality of data lines DL may be electrically connected to the data driver 700 of the driving part 100. The data lines DL may be electrically connected to the data driver 700 of the driving part 100 through a first through hole TSV1, the first scan lines GL1 may be electrically connected to the scan driver 610 through a second through hole TSV2, and the second scan lines GL2 may be electrically connected to the emission driver 620 through a third through hole TSV3.

Each of the plurality of sub-pixels SP1, SP2, and SP3 may be electrically connected to the scan lines GL1 and GL2 and the data line DL. Each of the plurality of sub-pixels SP1, SP2, and SP3 may receive a data voltage of the data line DL in response to a scan signal of the scan lines GL1 and GL2, and emit light from the light emitting element according to the data voltage.

The non-display area NA may be disposed to be around (e.g., to surround) the display area DAA. The non-display area NA may be an area where no pixels PX are disposed and therefore no light is emitted. The pad area PDA and a plurality of through holes TSV1, TSV2, TSV3, and TSV4 may be disposed in the non-display area NA.

The display device 10 may include the plurality of through holes TSV1, TSV2, TSV3, and TSV4 that form paths through which elements disposed in the driving part 100 and the display part 200 are electrically connected to each other. The plurality of through holes TSV1, TSV2, TSV3, and TSV4 may be formed to penetrate the second single crystal semiconductor substrate 210 of the display part 200. The driving circuit 400, the gate driver 600:610 and 620, and the data driver 700 disposed in the driving part 100 may be electrically connected to the display part 200 and the circuit board 300 through connection lines disposed in the through holes TSV1, TSV2, TSV3, and TSV4.

The plurality of through holes TSV1, TSV2, TSV3, and TSV4 may include the first through holes TSV1, the second through holes TSV2, the third through holes TSV3, and fourth through holes TSV4 disposed in the non-display area NA.

The first through holes TSV1 may be disposed in the non-display area NA on one side of the display area DAA in the second direction DR2. For example, the first through holes TSV1 may be disposed in the first through hole area TSA1 located to the upper side of the display area DAA. The first through holes TSV1 may be disposed to respectively correspond to the plurality of data lines DL disposed in the display area DAA. The number of the first through holes TSV1 may be equal to the number of the data lines DL and the number of pixel columns of the plurality of sub-pixels SP1, SP2, and SP3 disposed in the display area DAA. Each of the plurality of data lines DL may correspond to the first through hole TSV1 and may be electrically connected to the connection line disposed in the first through hole TSV1. Each of the sub-pixels SP1, SP2, and SP3 may receive a data signal from the data line DL connected to the data driver 700 of the driving part 100 through the first through hole TSV1.

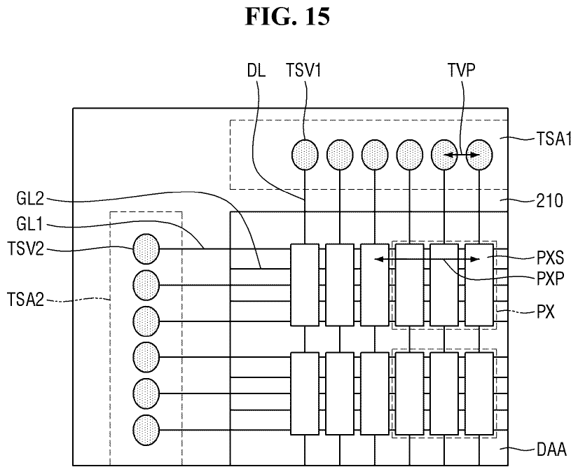

The second through holes TSV2 and the third through holes TSV3 may be disposed in the non-display area NA on both sides of the display area DAA in the first direction DR1, respectively. For example, the second through holes TSV2 may be disposed in the second through hole area TSA2 located to the left side of the display area DAA, and the third through holes TSV3 may be disposed in the third through hole area TSA3 located to the right side of the display area DAA. The second through holes TSV2 may be disposed to respectively correspond to the plurality of first scan lines GL1 disposed in the display area DAA, and the third through holes TSV3 may be disposed to respectively correspond to the plurality of second scan lines GL2 disposed in the display area DAA. The number of the second through holes TSV2 may be the same as the number of the first scan lines GL1, and the number of the third through holes TSV3 may be the same as the number of the second scan lines GL2. In FIG. 4, it is illustrated that one first scan line GL1 and one second scan line GL2 are connected to each of the sub-pixels SP1, SP2, and SP3. However, as will be described later with reference to FIG. 15, the sub-pixels SP1, SP2, and SP3 may each be connected to three first scan lines (e.g., the first to third scan lines GWL, GCL, and GBL in FIG. 5) and two second scan lines (e.g., first and second emission control lines EL1 and EL2 in FIG. 5). Accordingly, the number of the second through holes TSV2 may be equal to three times the number of pixel rows of the plurality of sub-pixels SP1, SP2, and SP3 disposed in the display area DAA, and the number of the third through holes TSV3 may be equal to twice the number of pixel rows of the plurality of sub-pixels SP1, SP2, and SP3 disposed in the display area DAA.

Each of the plurality of first scan lines GL1 may correspond to the second through hole TSV2 and may be electrically connected to the connection line disposed in the second through hole TSV2. Each of the sub-pixels SP1, SP2, and SP3 may receive a scan signal from the first scan line GL1 connected to the scan driver 610 of the driving part 100 through the second through hole TSV2. Each of the plurality of second scan lines GL2 may correspond to the third through hole TSV3 and may be electrically connected to the connection line disposed in the third through hole TSV3. Each of the sub-pixels SP1, SP2, and SP3 may receive an emission control signal from the second scan line GL2 connected to the emission driver 620 of the driving part 100 through the third through hole TSV3.

The fourth through holes TSV4 may be disposed in a fourth through hole area TSA4 of the non-display area NA. The fourth through hole area TSA4 may be disposed between the pad area PDA and the display area DAA. The fourth through hole TSV4 may be a connection path for a signal connection line electrically connecting the signal terminal STD of the driving part 100 to the circuit board 300. The plurality of fourth through holes TSV4 may be formed to respectively correspond to the signal terminals STD of the driving part 100. In one or more embodiments, the number of fourth through holes TSV4 may be equal to the number of signal terminals STD, and the fourth through holes TSV4 may be formed to respectively overlap the signal terminals STD. However, the present disclosure is not limited thereto. The circuit board 300 may be electrically connected to the signal terminal STD of the driving part 100 via a plurality of pads PD and the signal connection line disposed in the fourth through hole TSV4.

The pad area PDA may be disposed on a lower side of the display area DAA, which is one side in the second direction DR2. The plurality of pads PD arranged along the first direction DR1 may be disposed in the pad area PDA. The circuit board 300 may be attached onto the plurality of pads PD. The pads PD may be electrically connected to the circuit board 300, and may serve to transmit the electrical signal applied from the circuit board 300 to the driving part 100.

FIG. 5 is a block diagram illustrating a display device according to one or more embodiments.

Referring to FIG. 5, the driving circuit 400 may include a timing control circuit or a timing controller or a timing control circuit 410. In addition, the driving circuit 400 may further include various circuits involved in driving the display device 10, such as a gamma circuit and a logic circuit. The driving circuit 400 may include driving circuit transistors formed on the first single crystal semiconductor substrate 110.

The driving circuit 400 that includes the timing controller 410 may receive digital video data DATA and timing signals from the outside. The timing control circuit 410 may generate a scan timing control signal SCS, an emission timing control signal ECS, and a data timing control signal DCS for controlling the display part 200 according to the timing signals. The timing control circuit 410 may output the scan timing control signal SCS to the scan driver 610 of the gate driver 600, and may output the emission timing control signal ECS to the emission driver 620 of the gate driver 600. The timing control circuit 410 may output the digital video data DATA and the data timing control signal DCS to the data driver 700.

A power supply unit (e.g., power supply or power supply circuit) 800 may generate a plurality of panel driving voltages by an external power voltage. For example, the power supply unit 800 may generate a first driving voltage VSS, a second driving voltage VDD, a reference voltage VREF, and an initialization voltage VINT and supply them to the plurality of pixels PX.

The scan timing control signal SCS, the emission timing control signal ECS, digital video data DATA, and the data timing control signal DCS of the driving circuit 400 may be supplied to the plurality of pixels PX. The first driving voltage VSS, the second driving voltage VDD, the reference voltage VREF, and the initialization voltage VINT of the power supply unit 800 may also be supplied to the plurality of pixels PX.

The gate driver 600:610 and 620 may include the scan driver 610 and the emission driver 620. The scan driver 610 may include a plurality of scan transistors formed on the first single crystal semiconductor substrate 110, and the emission driver 620 includes a plurality of emission transistors formed on the first single crystal semiconductor substrate 110. The plurality of scan transistors and the plurality of emission transistors may be formed through a semiconductor process. For example, the plurality of scan transistors and the plurality of emission transistors may be formed as CMOS transistors.

The scan driver 610 may include a first scan signal output unit 611, a second scan signal output unit 612, and a third scan signal output unit 613. Each of the first scan signal output unit 611, the second scan signal output unit 612, and the third scan signal output unit 613 may receive the scan timing control signal SCS from the driving circuit 400. The first scan signal output unit 611 may generate write scan signals according to the scan timing control signal SCS of the driving circuit 400 and output them sequentially to first scan lines GWL. The second scan signal output unit 612 may generate control scan signals in response to the scan timing control signal SCS and sequentially output them to the second scan lines GCL. The third scan signal output unit 613 may generate bias scan signals according to the scan timing control signal SCS and output them sequentially to third scan lines GBL.

The emission driver 620 may include a first emission signal output unit 621 and a second emission signal output unit 622. Each of the first emission signal output unit 621 and the second emission signal output unit 622 may receive the emission timing control signal ECS from the driving circuit 400. The emission driver 620 may generate emission control signals according to the emission timing control signal ECS and sequentially output them to the first and second emission control lines EL1 and EL2.

The data driver 700 may receive the digital video data DATA and the data timing control signal DCS from the driving circuit 400. The data driver 700 converts the digital video data DATA into analog data voltages according to the data timing control signal DCS and outputs the analog data voltages to data lines DL. In this case, the sub-pixels SP1, SP2, and SP3 are selected by the write scan signal of the scan driver 610, and data voltages may be supplied to the selected sub-pixels SP1, SP2, and SP3.

FIG. 6 is an equivalent circuit diagram of one pixel according to one or more embodiments.

Referring to FIG. 6, the pixel circuit PXC (e.g., 220) of the sub-pixels SP1, SP2, and SP3 may be connected to the first scan line GWL, the second scan line GCL, the third scan line GBL, the first emission control line EL1, the second emission control line EL2, and the data line DL. In addition, the pixel circuit PXC may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The pixel circuit PXC of the sub-pixels SP1, SP2, and SP3 includes a plurality of transistors T1 to T6, a light emitting element LE, a first capacitor C1, and a second capacitor C2.

The light emitting element LE emits light in response to a driving current Ids flowing through the channel of a first transistor T1. The emission amount of the light emitting element LE may be proportional to the driving current Ids. The light emitting element LE may be disposed between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be disposed between one electrode of the first capacitor C1 and the data line DL. The second transistor T2 is turned on by the write scan signal of the first scan line GWL to connect the one electrode of the first capacitor C1 to the data line DL. Accordingly, the data voltage of the data line DL may be applied to the one electrode of the first capacitor C1. The second transistor T2 includes a gate electrode connected to the first scan line GWL, a source electrode connected to the data line DL, and a drain electrode connected to the one electrode of the first capacitor C1.

A third transistor T3 may be disposed between the first node N1 and the second node N2. The third transistor T3 is turned on by the write control signal of the second scan line GCL to connect the first node N1 to the second node N2. For this reason, because the gate electrode and the source electrode of the first transistor T1 are connected, the first transistor T1 may operate like a diode (e.g., the first transistor T1 may be diode-connected). The third transistor T3 includes a gate electrode connected to the second scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current Ids of the first transistor T1 may be supplied to the light emitting element LE. The fourth transistor T4 includes a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the third scan line GBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the third scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 (e.g., the first node N1) and the second driving voltage line VDL. The second capacitor C2 includes one electrode connected to the gate electrode of the first transistor T1 (e.g., the first node N1) and the other electrode connected to the second driving voltage line VDL.

The first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 6 illustrates that the pixel circuit PXC of the sub-pixels SP1, SP2, and SP3 includes six transistors T1 to T6 and two capacitors C1 and C2, it should be noted that the equivalent circuit diagram of the sub-pixel SP is not limited to that shown in FIG. 6. For example, the number of the transistors and the number of the capacitors of the pixel circuit PXC are not limited to the example shown in FIG. 6.

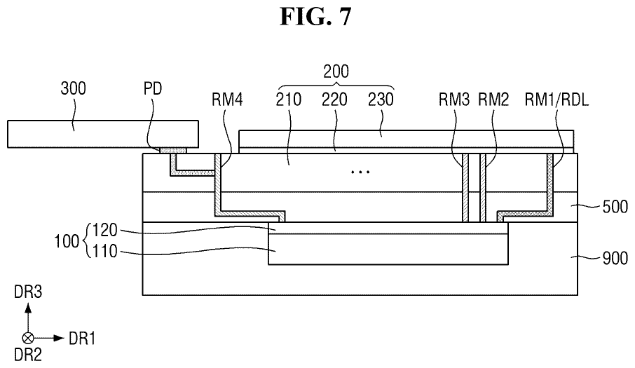

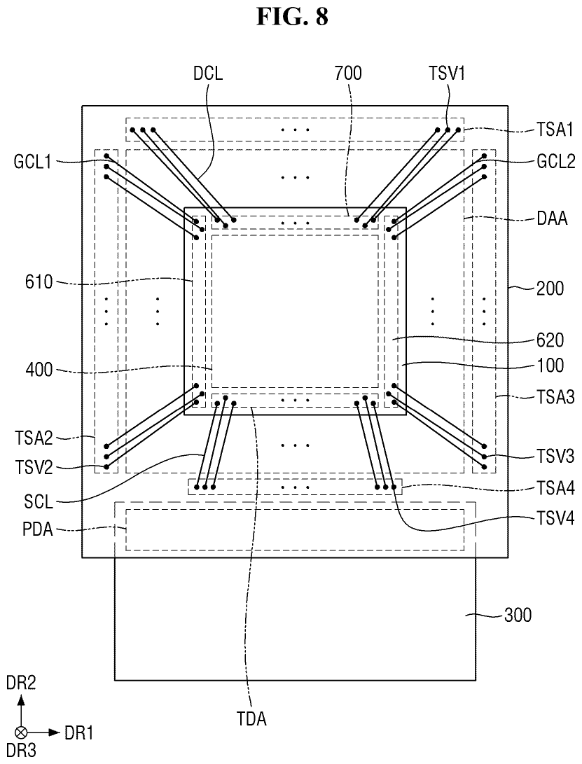

FIG. 7 is a schematic cross-sectional view of a display device according to one or more embodiments. FIG. 8 is a schematic diagram showing a rear surface of a display device according to one or more embodiments. FIG. 7 illustrates a schematic connection relationship of routing lines RM1, RM2, RM3, and RM4 electrically connecting the display part 200 to the driving part 100. FIG. 8 illustrates the disposition of the through holes TSV1, TSV2, TSV3, and TSV4 and routing lines RDL, GCL1, GCL2, and SCL viewed from the rear of the display device 10.

Referring to FIGS. 7 and 8 in conjunction with FIG. 4, the display device 10 according to one or more embodiments may include the driving part 100 including the first single crystal semiconductor substrate 110 and a driving circuit layer 120 disposed on the first single crystal semiconductor substrate 110; and the display part 200 including the second single crystal semiconductor substrate 210, and the pixel circuit 220 and the display layer 230 disposed on the second single crystal semiconductor substrate 210. The display device 10 may include the two different single crystal semiconductor substrates 110 and 210 overlapping each other in the third direction DR3, which is the thickness direction of the display device 10.

The driving part 100 may include circuit elements necessary for light emission of the light emitting elements included in the display layer 230 of the display part 200. As described above, the driving circuit layer 120 of the driving part 100 may include the driving circuit 400, the gate driver 600, and the data driver 700, and the circuit elements constituting them, such as transistors and capacitors, may be formed of CMOS on the first single crystal semiconductor substrate 110.

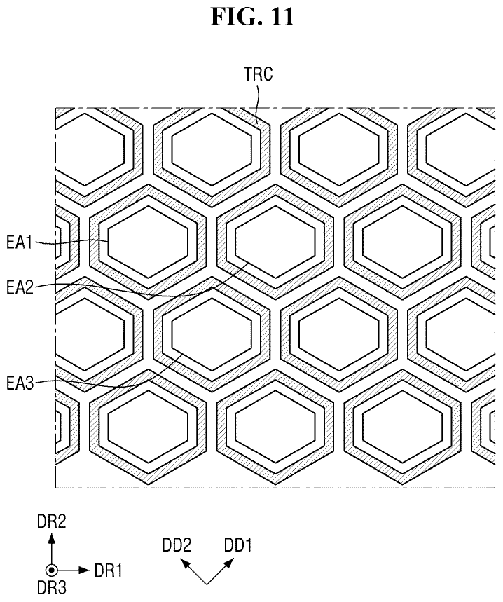

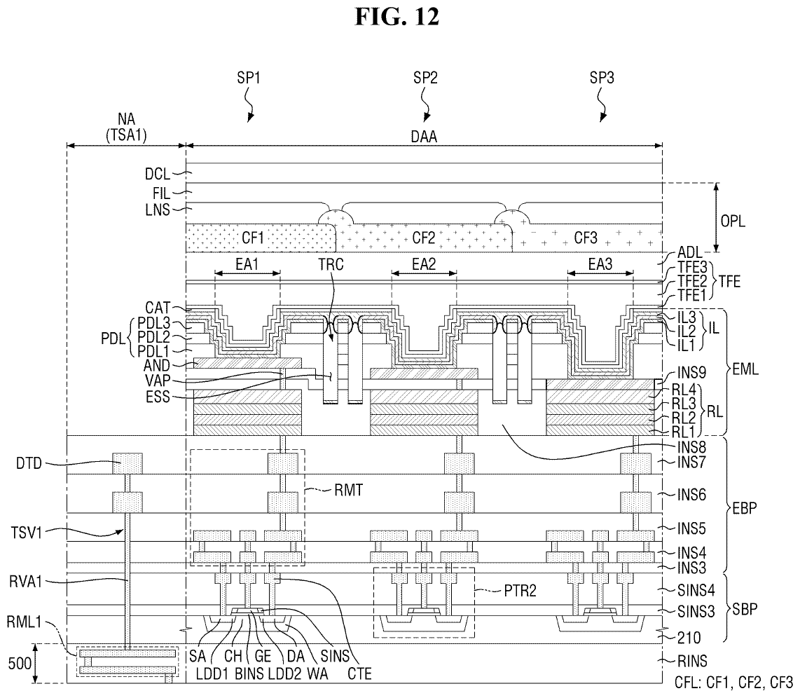

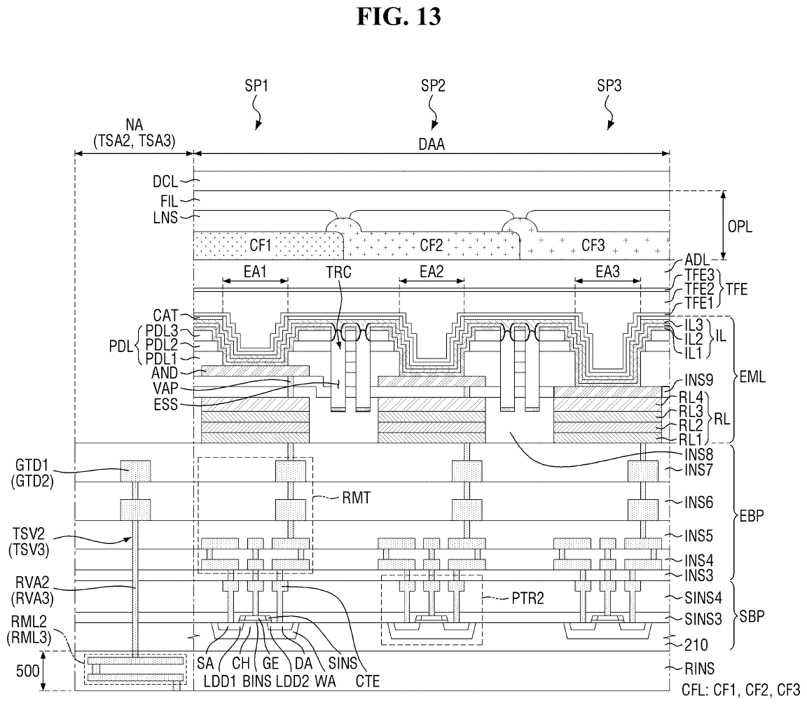

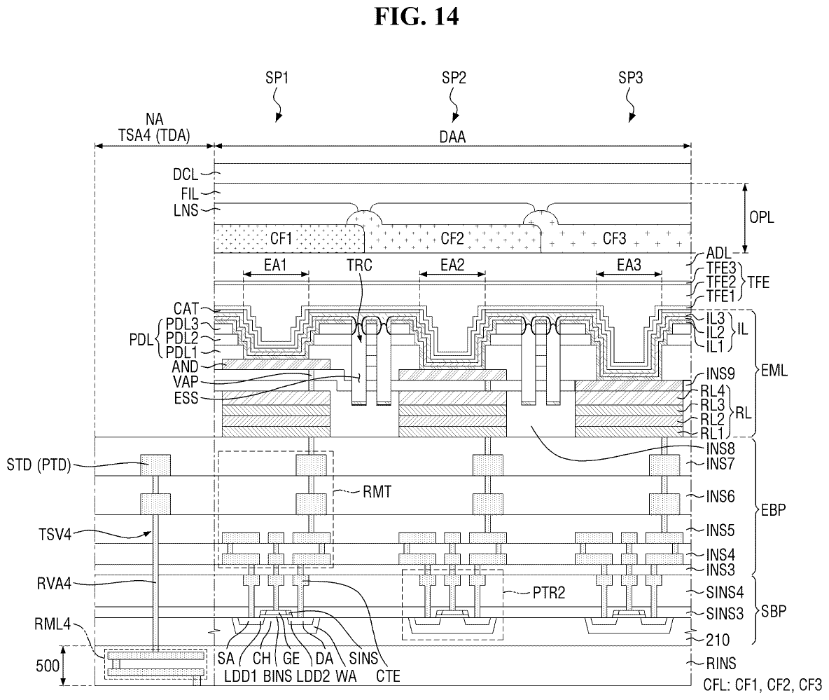

The display part 200 may include a plurality of light emitting elements that emit light to display an image of the display device 10. The light emitting elements may be electrically connected to the circuit elements formed in the driving part 100 to emit light. In addition, the display part 200 may include the pixel circuit 220 in which circuit elements constituting the pixel circuit PXC electrically connected to each of the sub-pixels SP1, SP2, and SP3 are disposed. The pixel circuit 220 may include the circuit elements, e.g., the first to sixth transistors T1 to T6 in FIG. 6, constituting the pixel circuit, the plurality of scan lines GL1 and GL2, and the data lines DL. The pixel circuit 220 may also include a plurality of terminals DTD, GTD1, GTD2, and PTD (see FIGS. 12 to 14) connected to the through holes TSV1, TSV2, TSV3, and TSV4 disposed in the non-display area NA of the display part 200.

According to one or more embodiments, in the display device 10, in a plan view, the area of the driving part 100 or the first single crystal semiconductor substrate 110 may be smaller than the area of the display part 200 or the second single crystal semiconductor substrate 210. A plurality of transistors formed in the driving part 100 may be formed through a semiconductor micro-process, and thus may have a very small size or line width. In the driving part 100, because a large number of circuit elements may be disposed with a high integration density, power consumption may be reduced due to the miniaturization of the elements.

In addition, because the driving part 100 includes only the circuit elements formed of CMOS on the first single crystal semiconductor substrate 110 and does not include light emitting elements, the driving part 100 only needs to secure a space for accommodating the elements formed by the micro-process therein. It still works even if the first single crystal semiconductor substrate 110 has a smaller area than the second single crystal semiconductor substrate 210, and a large number of driving parts 100 may be fabricated on a single wafer substrate on which the process of forming the driving circuit layer 120 is performed, so that the fabrication yield may be improved. In particular, because a high-cost semiconductor process is performed to fabricate the driving part 100, such improvement in the fabrication yield of the driving part 100 may lead to cost reduction. Further, in the display part 200, because a large number of light emitting elements can be formed on the second single crystal semiconductor substrate 210 having a relatively large area, a high-resolution display device may be implemented.

The display device 10 may include a connection line layer 500 disposed between the second single crystal semiconductor substrate 210 of the display part 200 and the driving circuit layer 120 of the driving part 100. The connection line layer 500 may be disposed on the bottom surface of the second single crystal semiconductor substrate 210. Portions of the plurality of routing lines RM1, RM2, RM3, and RM4 may be disposed in the connection line layer 500, and the routing lines RM1, RM2, RM3, and RM4 may connect the pixel circuit 220 of the display part 200 and the circuit board 300 to the driving part 100. The driving circuit layer 120 of the driving part 100 may be electrically connected to the display part 200 and the circuit board 300 through the routing lines RM1, RM2, RM3, and RM4 of the connection line layer 500 to transmit an electrical signal for light emission.

A first routing line RM1 may be connected to the data line DL disposed in the display part 200 and the data driver 700 disposed in the driving part 100. The first routing line RM1 may be disposed in the first through hole TSV1 formed in the second single crystal semiconductor substrate 210, and may include a data routing line RDL of the connection line layer 500. The plurality of first through holes TSV1 may be disposed in the first through hole area TSA1 of the non-display area NA of the display part 200, and may not overlap the driving part 100 in the thickness direction (e.g., the third direction DR3). The first routing line RM1 may be partially disposed in the first through hole TSV1, and the data routing line RDL may be disposed in the connection line layer 500 and may connect the first through hole TSV1 that does not overlap the driving part 100 to the data driver 700.

A second routing line RM2 may be connected to the first scan line GL1 or the first to third scan lines GWL, GCL, and GBL disposed in the display part 200, and the scan driver 610 disposed in the driving part 100. The second routing line RM2 may be disposed in the second through hole TSV2 formed in the second single crystal semiconductor substrate 210, and may include a first scan routing line GCL1 of the connection line layer 500. The plurality of second through holes TSV2 may be disposed in the second through hole area TSA2 of the non-display area NA of the display part 200, and may not overlap the driving part 100 in the thickness direction (e.g., the third direction DR3). The second routing line RM2 may be partially disposed in the second through hole TSV2, and the first scan routing line GCL1 may be disposed in the connection line layer 500 and may connect the second through hole TSV2 that does not overlap the driving part 100 to the scan driver 610.

A third routing line RM3 may be connected to the second scan line GL2 or the first and second emission control lines EL1 and EL2 disposed in the display part 200, and the emission driver 620 disposed in the driving part 100. The third routing line RM3 may be disposed in the third through hole TSV3 formed in the second single crystal semiconductor substrate 210, and may include a second scan routing line GCL2 of the connection line layer 500. The plurality of third through holes TSV3 may be disposed in the third through hole area TSA3 of the non-display area NA of the display part 200, and may not overlap the driving part 100 in the thickness direction (e.g., the third direction DR3). The third routing line RM3 may be partially disposed in the third through hole TSV3, and the second scan routing line GCL2 may be disposed in the connection line layer 500 and may connect the third through hole TSV3 that does not overlap the driving part 100 to the emission driver 620.

According to one or more embodiments, the number of the first through holes TSV1 may be equal to the number of pixel columns of the plurality of sub-pixels SP1, SP2, and SP3 disposed in the display area DAA. For example, the plurality of sub-pixels SP1, SP2, and SP3 may be arranged along the first direction DR1 and the second direction DR2 in the display area DAA, and when the number of pixel columns arranged along the first direction DR1 is 4000, the number of the first through holes TSV1 may also be equal to 4000. The first through holes TSV1 may correspond to the pixel columns of the sub-pixels SP1, SP2, and SP3 arranged along the first direction DR1 in a one-to-one manner, and may also correspond to the plurality of data lines DL arranged along the first direction DR1 and the first routing line RM1 in a one-to-one manner. One data line DL disposed in parallel with one pixel column may be connected to the data driver 700 through the first routing line RM1 disposed in one first through hole TSV1. The first routing line RM1 and the first through holes TSV1 may each be disposed in the same number as the number of the plurality of pixel columns and the number of the data lines DL.

On the other hand, the number of the second through holes TSV2 and the third through holes TSV3 may be greater than the number of pixel rows of the plurality of sub-pixels SP1, SP2, and SP3 disposed in the display area DAA. As described above, because two or more scan lines GL1 and GL2 are disposed in one sub-pixel SP1, SP2, SP3, three second through holes TSV2 and two third through holes TSV3 may be disposed to correspond to one sub-pixel row. However, the plurality of second through holes TSV2 may correspond to the second routing line RM2 and the plurality of first scan lines GL1 arranged along the second direction DR2 in a one-to-one manner, and the plurality of third through holes TSV3 may correspond to the third routing line RM3 and the plurality of second scan lines GL2 arranged along the second direction DR2 in a one-to-one manner.

The plurality of data lines DL may extend in the second direction DR2 and may be connected respectively to the first through holes TSV1 in a parallel manner without being bent even in the non-display area NA. The plurality of scan lines GL1 and GL2 may also extend in the first direction DR1 and may be connected to the second through hole TSV2 and the third through hole TSV3, respectively, in a parallel manner without being bent even in the non-display area NA. The display device 10 may maintain a constant gap of the signal lines in the display area DAA and the non-display area NA of the display part 200, and may omit a fan-out structure in which the signal lines bend and narrow in width in the non-display area NA. A gap of the first through holes TSV1, the second through holes TSV2, and the third through holes TSV3 may also be constant, similarly to that of the signal lines. However, the routing lines, e.g., the data routing line RDL and the scan routing lines GCL1 and GCL2, disposed on the rear surface of the display part 200 may connect the display part 200 to the driving part 100 having a small area, starting from the edge of the display part 200, so that the gap thereof may become small as they approach the driving part 100.

A fourth routing line RM4 may be connected to the circuit board 300 through the pads PD disposed in the display part 200, and may be connected to the signal terminal STD of the driving part 100. The fourth routing line RM4 may be disposed in the fourth through hole TSV4 formed in the second single crystal semiconductor substrate 210, and may include a signal routing line SCL of the connection line layer 500. The plurality of fourth through holes TSV4 may be disposed in the fourth through hole area TSA4 of the non-display area NA of the display part 200, and may not overlap the driving part 100 in the thickness direction (e.g., the third direction DR3). The fourth routing line RM4 may be partially disposed in the fourth through hole TSV4, and the signal routing line SCL may be disposed in the connection line layer 500 and may connect the fourth through hole TSV4 that does not overlap the driving part 100 to the signal terminal STD. The fourth routing line RM4 may be a wire that transmits a signal applied from the circuit board 300 to the driving part 100.

The routing lines RM1, RM2, RM3, and RM4 may include connection lines RML1, RML2, RML3, and RML4 (see FIGS. 12, 13 and 14) disposed in the connection line layer 500, and conductive vias RVA1, RVA2, RVA3, and RVA4 (see FIGS. 12-14) disposed in the through holes TSV1, TSV2, TSV3, and TSV4 of the second single crystal semiconductor substrate 210. The routing lines RM1, RM2, RM3, and RM4 are wires that electrically connect layers disposed on and below the second single crystal semiconductor substrate 210, and the disposition and design of the through holes formed in the second single crystal semiconductor substrate 210 may vary depending on the disposition of the layers electrically connected to the routing lines RM1, RM2, RM3, and RM4.

Hereinafter, the structures of the driving circuit layer 120 of the driving part 100, and the pixel circuit 220 and the display layer 230 of the display part 200 will be described in detail with reference to other drawings.

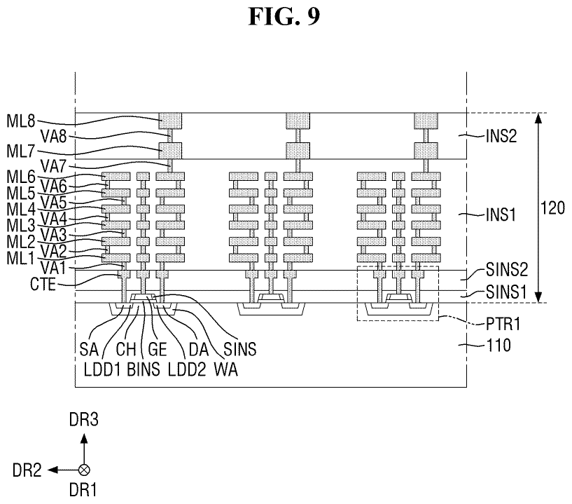

FIG. 9 is a schematic cross-sectional view of a driving part according to one or more embodiments.

Referring to FIG. 9, the driving part 100 may include the first single crystal semiconductor substrate 110 and the driving circuit layer 120 disposed thereon. FIG. 9 schematically shows the cross-sectional structure of the data driver 700 from among the circuit units disposed in the driving part 100.

The first single crystal semiconductor substrate 110 may be a silicon substrate, a germanium substrate, and/or a silicon-germanium substrate. The first single crystal semiconductor substrate 110 may be a substrate doped with a first type impurity. A plurality of well regions WA may be disposed on the top surface of the first single crystal semiconductor substrate 110. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of a first transistor PTR1, a drain region DA corresponding to the drain electrode thereof, and a channel region CH disposed between the source region SA and the drain region DA.

A lower insulating film BINS may be disposed between a gate electrode GE of the first transistor PTR1 and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the first transistor PTR1 may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the first transistors PTR1 may increase, so that punch-through and hot carrier phenomena that might be caused by a short channel may be prevented.

The first single crystal semiconductor substrate 110 may include the plurality of first transistors PTR1 constituting a plurality of circuit elements of the driving part 100. The first transistors PTR1 formed on the first single crystal semiconductor substrate 110 may constitute the driving circuit 400 or the data driver 700.

When the driving circuit layer 120 is formed on a silicon wafer substrate, a process of reducing the thickness of the first single crystal semiconductor substrate 110 may be performed. The first single crystal semiconductor substrate 110 may have a thickness smaller than that of a wafer substrate on which a semiconductor process for forming the driving circuit layer 120 is performed. In one or more embodiments, the thickness of the first single crystal semiconductor substrate 110 may be 100 μm or less, for example, in the range of 80 μm to 100 μm.

The driving circuit layer 120 may include a first semiconductor insulating layer SINS1, a second semiconductor insulating layer SINS2, a plurality of contact electrodes CTE, a first interlayer insulating layer INS1, a second interlayer insulating layer INS2, a plurality of conductive layers ML1 to ML8, and a plurality of vias VA1 to VA8. The driving circuit layer 120 may include wires electrically connected to the plurality of first transistors PTR1 included in the first single crystal semiconductor substrate 110.

The first semiconductor insulating layer SINS1 and the second semiconductor insulating layer SINS2 may be disposed on the first single crystal semiconductor substrate 110. The first semiconductor insulating layer SINS1 may be an insulating layer disposed on the first single crystal semiconductor substrate 110 and the gate electrode GE of the first transistor PTR1, and the second semiconductor insulating layer SINS2 may be an insulating layer disposed on the gate electrode GE of the first transistor PTR1 and the first semiconductor insulating layer SINS1. The first semiconductor insulating layer SINS1 and the second semiconductor insulating layer SINS2 may be formed of a silicon carbon nitride (SiCN) and/or silicon oxide (SiOₓ)-based inorganic film, but are not limited thereto. In the drawing, the first semiconductor insulating layer SINS1 and the second semiconductor insulating layer SINS2 are each shown as an example of a single layer having a suitable thickness (e.g., a predetermined thickness), but are not limited thereto. The first semiconductor insulating layer SINS1 and the second semiconductor insulating layer SINS2 may have a structure in which one or more layers are stacked on top of each other.

The plurality of contact electrodes CTE may be disposed on the first single crystal semiconductor substrate 110. The plurality of contact electrodes CTE may be connected to one of the gate electrodes GE, the source region SA, or the drain region DA of each first transistor PTR1 formed on the first single crystal semiconductor substrate 110 through holes penetrating the semiconductor insulating layers SINS1 and SINS2. The plurality of contact electrodes CTE may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. The top surfaces of the plurality of contact electrodes CTE may be exposed without being covered by the semiconductor insulating layers SINS1 and SINS2.

The first interlayer insulating layer INS1 may be disposed on the plurality of contact electrodes CTE and the semiconductor insulating layers SINS1 and SINS2. The second interlayer insulating layer INS2 may be disposed on the first interlayer insulating layer INS1. Each of the first interlayer insulating layer INS1 and the second interlayer insulating layer INS2 may be formed of silicon carbonitride (SiCN) and/or a silicon oxide (SiOx)-based inorganic film, but is not limited thereto. Although it is illustrated in the drawings that each of the first interlayer insulating layer INS1 and the second interlayer insulating layer INS2 is formed as a single layer, the present disclosure is not limited thereto. Each of the first interlayer insulating layer INS1 and the second interlayer insulating layer INS2 may have a structure in which one or more layers are stacked on top of each other, and may be disposed between a plurality of first to eighth conductive layers ML1 to ML8 to be described later.

The first to eighth conductive layers ML1 to ML8 and first to eighth vias VA1 to VA8 may be electrically connected to the plurality of contact electrodes CTE to form the driving circuit 400 or the data driver 700 of the driving part 100. The plurality of first transistors PTR1 formed on the first single crystal semiconductor substrate 110 may be electrically connected to each other through the first to eighth conductive layers ML1 to ML8 and the first to the eighth vias VA1 to VA8, and may form the driving circuit 400, and the data driver 700 of the driving part 100.

The first conductive layer ML1 may be connected to the contact electrode CTE through the first via VA1. The first conductive layer ML1 may be disposed on the contact electrode CTE, and the first via VA1 may be disposed between the first conductive layer ML1 and the contact electrode CTE to be in contact with both of them. The second conductive layer ML2 may be connected to the first conductive layer ML1 through the second via VA2. The second conductive layer ML2 may be disposed on the first conductive layer ML1, and the second via VA2 may be disposed between the first conductive layer ML1 and the second conductive layer ML2 to be in contact with both of them.

The third conductive layer ML3 may be connected to the second conductive layer ML2 through the third via VA3. The fourth conductive layer ML4 may be connected to the third conductive layer ML3 through the fourth via VA4, the fifth conductive layer ML5 may be connected to the fourth conductive layer ML4 through the fifth via VA5, and the sixth conductive layer ML6 may be connected to the fifth conductive layer ML5 through the sixth via VA6. The third conductive layer ML3, the fourth conductive layer ML4, the fifth conductive layer ML5, and the sixth conductive layer ML6 may be sequentially disposed on the second conductive layer ML2, and the third via VA3, the fourth via VA4, the fifth via VA5, and the sixth via VA6 may be disposed between them. The third to sixth vias VA3 to VA6 may be in contact with different metal layers disposed above and below them, respectively. The seventh via VA7 may be disposed on the sixth conductive layer ML6. The seventh via VA7 may be in contact with the seventh conductive layer ML7 and the sixth conductive layer ML6 disposed thereon.

The first to sixth conductive layers ML1 to ML6 and the first to seventh vias VA1 to VA7 may be disposed in the first interlayer insulating layer INS1. The first to sixth conductive layers ML1 to ML6 and the first to seventh vias VA1 to VA7 may constitute a first driving circuit layer disposed in the first interlayer insulating layer INS1 of the driving circuit layer 120.

The seventh conductive layer ML7 may be connected to the sixth conductive layer ML6 through the seventh via VA7. The seventh conductive layer ML7 may be disposed on the first interlayer insulating layer INS1 and the sixth conductive layer ML6, and the seventh via VA7 may be disposed between the sixth conductive layer ML6 and the seventh conductive layer ML7 to be in contact with both of them. The eighth conductive layer ML8 may be connected to the seventh conductive layer ML7 through the eighth via VA8. The eighth conductive layer ML8 is disposed on the seventh conductive layer ML7, and the eighth via VA8 may be disposed between the seventh conductive layer ML7 and the eighth conductive layer ML8 to be in contact with both of them. The top surface of the eighth conductive layer ML8 may be exposed without being covered by the second interlayer insulating layer INS2, and may be electrically connected to the routing lines RM disposed in the display part 200.

The seventh conductive layer ML7, the eighth via VA8, and the eighth conductive layer ML8 may be disposed in the second interlayer insulating layer INS2. The seventh conductive layer ML7, the eighth via VA8, and the eighth conductive layer ML8 may constitute a second driving circuit layer disposed in the second interlayer insulating layer INS2 of the driving circuit layer 120.

In the drawings, although the first to eighth conductive layers ML1 to ML8 and the first to eighth vias VA1 to VA8 are illustrated as being sequentially stacked on top of each other, their layout and connection may be modified in various ways according to the circuits of the driving circuit 400, and the data driver 700 of the driving part 100. The connection structure shown in the drawings is nothing more than an example, and the connection of the driving circuit layer 120 disposed in the driving part 100 of the display device 10 is not limited thereto. In addition, the driving circuit layer 120 may not necessarily include the first to eighth conductive layers ML1 to ML8 and the first to eighth vias VA1 to VA8, and some of these layers may be omitted or more layers may be provided.

The first to eighth conductive layers ML1 to ML8 and the first to eighth vias VA1 to VA8 may be formed of substantially the same material. For example, the first to eighth conductive layers ML1 to ML8 and the first to eighth vias VA1 to VA8 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å; the thickness of each of the second conductive layer ML2, the third conductive layer ML3, the fourth conductive layer ML4, the fifth conductive layer ML5, and the sixth conductive layer ML6 may be approximately 1440 Å; and the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

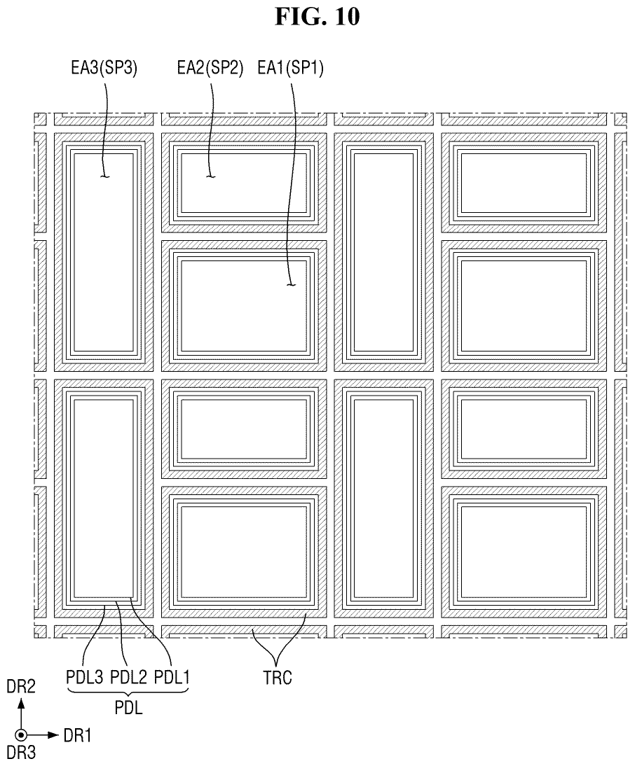

FIG. 10 is a plan view showing a pixel defining film, and first electrodes and emission areas of a plurality of sub-pixels disposed in a display area of a display part according to one or more embodiments.

Referring to FIG. 10, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may have, in a plan view, a quadrilateral shape such as a rectangle, a square, and/or a diamond. For example, the third emission area EA3 may have a rectangular shape, in a plan view, having a short side in the first direction DR1 and a long side in the second direction DR2. In addition, each of the second emission area EA2 and the first emission area EA1 may have a rectangular shape, in a plan view, having a long side in the first direction DR1 and a short side in the second direction DR2.

Each of the first emission area EA1, the second emission area EA2, and the third emission area EA3 may be an area defined by a pixel defining film PDL. For example, each of the first emission area EA1, the second emission area EA2, and the third emission area EA3 may be an area defined by a first pixel defining film PDL1.

The length of the third emission area EA3 in the first direction DR1 may be smaller than the length of the first emission area EA1 in the first direction DR1, and may be smaller than the length of the second emission area EA2 in the first direction DR1. The length of the first emission area EA1 in the first direction DR1 and the length of the second emission area EA2 in the first direction DR1 may be substantially the same.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different.

Although it is illustrated in the drawing that each of the first emission area EA1, the second emission area EA2, and the third emission area EA3 has a rectangular shape in a plan view, the present disclosure is not limited thereto. For example, each of the first emission area EA1, the second emission area EA2, and the third emission area EA3 may have a polygonal shape other than a quadrilateral shape, a circular shape, and/or an elliptical shape in a plan view.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

A first electrode AND (e.g., see FIG. 12) of the light emitting element may have a rectangular shape in a plan view. The planar shape of the first electrode AND of the light emitting element may be different in the first sub-pixel SP1, the second sub-pixel SP2, and the third sub-pixel SP3. For example, the first electrode AND of the first sub-pixel SP1 and the first electrode AND of the second sub-pixel SP2 may have a rectangular planar shape having a long side in the first direction DR1 and a short side in the second direction DR2. The first electrode AND of the third sub-pixel SP3 may have a rectangular shape, in a plan view, having a short side in the first direction DR1 and a long side in the second direction DR2. The length of the first electrode AND of the third sub-pixel SP3 in the first direction DR1 may be shorter than the length of the first electrode AND of each of the first sub-pixel SP1 and the second sub-pixel SP2 in the second direction DR2. The length of the first electrode AND of the first sub-pixel SP1 in the second direction DR2 may be greater than the length of the first electrode AND of the second sub-pixel SP2 in the second direction DR2.

The first electrode AND of the light emitting element may be connected to a reflective electrode layer RL (e.g., see FIG. 12) via an electrode via VAP (e.g., see FIG. 12). The electrode via VAP may overlap the first pixel defining film PDL1, a second pixel defining film PDL2, and a third pixel defining film PDL3 in the third direction DR3.

At least one trench TRC may be a structure for cutting off at least one charge generation layer of a light emitting stack IL between the neighboring emission areas EA1, EA2, and EA3 (e.g., see FIG. 12). At least one trench TRC may be disposed between the first emission area EA1 and the second emission area EA2, between the first emission area EA1 and the third emission area EA3, and between the second emission area EA2 and the third emission area EA3. More specifically, at least one trench TRC may be disposed between the first electrode AND of the first sub-pixel SP1 and the first electrode AND of the second sub-pixel SP2, between the first electrode AND of the first sub-pixel SP1 and the first electrode AND of the third sub-pixel SP3, and between the first electrode AND of the second sub-pixel SP2 and the first electrode AND of the third sub-pixel SP3.

FIG. 11 is a plan view showing a pixel defining film, and first electrodes and emission areas of a plurality of sub-pixels disposed in a display area of a display part according to one or more embodiments.

Referring to FIG. 11, the embodiment of FIG. 11 is substantially the same as the embodiment of FIG. 10 except that the planar shapes of the first emission area EA1, the second emission area EA2, and the third emission area EA3 are different from those of the embodiment of FIG. 10, description overlapping with the embodiment of FIG. 10 will be omitted.

The first emission area EA1, the second emission area EA2, and the third emission area EA3 may be disposed in a hexagonal structure having a hexagonal shape in a plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

Although it is illustrated in FIGS. 10 and 11 that each of the plurality of pixels PX includes the three emission areas EA1, EA2, and EA3, the present disclosure is not limited thereto. That is, each of the plurality of pixels PX may include four emission areas.

In addition, the layout of the emission areas of the plurality of pixels PX is not limited to that illustrated in the drawing. For example, the emission areas of the plurality of pixels PX may be disposed in a stripe structure in which the emission areas are arranged along the first direction DR1, a PENTILE® structure in which the emission areas are arranged in a diamond shape, and/or a hexagonal structure in which the emission areas having, in a plan view, a hexagonal shape are arranged side by side. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

FIGS. 12-14 are cross-sectional views showing a portion of a display area and a portion of a non-display area in a display part according to one or more embodiments. FIGS. 12-14 disclose a schematic cross-sectional structure of the display area DAA, the non-display area NA, and the pad area PDA.

Referring to FIGS. 12-14, the display part 200 may include a semiconductor backplane SBP, a pixel circuit backplane EBP, a display element layer EML, an encapsulation layer TFE, an adhesive layer ADL, a color filter layer CFL, a lens LNS, and a cover layer DCL. The semiconductor backplane SBP and the pixel circuit backplane EBP of the display part 200 may constitute the pixel circuit 220. The display element layer EML, the encapsulation layer TFE, the adhesive layer ADL, an optical layer OPL including the color filter layer CFL, the lens LNS, and a filling layer FIL, and the cover layer DCL of the display part 200 may constitute the display layer 230. In one or more embodiments, the display part 200 may further include a polarizing plate disposed on the cover layer DCL. The connection line layer 500 may be disposed between the first single crystal semiconductor substrate 110 and the second single crystal semiconductor substrate 210 of the semiconductor backplane SBP. Alternatively, the connection line layer 500 may be disposed between the display element layer EML and the first single crystal semiconductor substrate 110.

The semiconductor backplane SBP includes the second single crystal semiconductor substrate 210 including a plurality of second transistors PTR2, a plurality of semiconductor insulating films disposed on the plurality of second transistors PTR2, and the plurality of contact electrodes CTE respectively electrically connected to the plurality of pixel transistors. The plurality of second transistors PTR2 may be the first to sixth transistors T1 to T6 constituting the pixel circuit of FIG. 6, or may be the scan transistors of the gate driver 610 and 620.

The second single crystal semiconductor substrate 210 may be a silicon substrate, a germanium substrate, and/or a silicon-germanium substrate. The second single crystal semiconductor substrate 210 may be a substrate doped with an impurity. The plurality of well regions WA may be disposed on the top surface of the second single crystal semiconductor substrate 210. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

The second single crystal semiconductor substrate 210 may include the plurality of second transistors PTR2, similarly to the first single crystal semiconductor substrate 110. The structure of the second transistor PTR2 may be the same as that of the first transistor PTR1, and therefore, a detailed description thereof will be omitted.

In the display device 10, wafer substrates on which the first transistor PTR1 formed on the first single crystal semiconductor substrate 110 of the driving part 100, and the second transistor PTR2 formed on the second single crystal semiconductor substrate 210 of the display part 200 are formed may be different. According to one or more embodiments, in the display device 10, the first transistor PTR1 formed on the first single crystal semiconductor substrate 110 and the second transistor PTR2 formed on the second single crystal semiconductor substrate 210 may have different sizes, line widths, and/or the like.

For example, in the display device 10, the minimum line width of the first transistor PTR1 formed on the first single crystal semiconductor substrate 110 may be smaller than the minimum line width of the second transistor PTR2 formed on the second single crystal semiconductor substrate 210. The semiconductor process performed on a first wafer substrate for the formation of the first transistor PTR1 is a process having higher resolution than the semiconductor process performed on a second wafer substrate for the formation of the second transistor PTR2, and thus the size of an element such as a fabricated transistor may be smaller. In other words, the semiconductor process performed on the first wafer substrate may be a finer process than the semiconductor process performed on the second wafer substrate.

As described above, the first single crystal semiconductor substrate 110 of the driving part 100 may have a smaller area in a plan view than the second single crystal semiconductor substrate 210 of the display part 200, and small-sized elements may be disposed with a high integration density to reduce power consumption and improve fabrication yield. On the other hand, the second single crystal semiconductor substrate 210 of the display part 200 may have a larger area in a plan view than the first single crystal semiconductor substrate 110, and a process with a relatively large linewidth may be performed. The second transistors PTR2 disposed in the second single crystal semiconductor substrate 210 may be formed in a larger area than when formed in the first single crystal semiconductor substrate 110, and the second transistors PTR2 constituting the pixel circuit may not require a high integration density. Accordingly, the semiconductor process performed on the first wafer substrate may be performed as a high-cost process having a small line width, and the semiconductor process performed on the second wafer substrate may be performed as a low-cost process having a relatively large line width.

In one or more embodiments, the lengths of the channel regions CH of the plurality of transistors PTR1 and PTR2 may be different from each other, and the minimum line width or a length of the channel region CH of the first transistor PTR1 may be smaller than the minimum line width or a length of the channel region CH of the second transistor PTR2. The minimum line width or the length of the channel region CH of the first transistor PTR1 may be equal to or less than 100 nm, or may range from 2 nm to 80 nm. The minimum line width or the length of the channel region CH of the second transistor PTR2 may be greater than or equal to 100 nm, or may range from 100 nm to 5 μm.

The second single crystal semiconductor substrate 210 may include the plurality of through holes TSV1, TSV2, TSV3, and TSV4 spaced (e.g., spaced apart) from each other. The through holes TSV1, TSV2, TSV3, and TSV4 may penetrate from the top surface of the second single crystal semiconductor substrate 210 to the bottom surface thereof, and may also penetrate a plurality of semiconductor insulating layers SINS3 and SINS4 and interlayer insulating layers INS3, INS4, and INS5 disposed on the second single crystal semiconductor substrate 210. The conductive vias RVA1, RVA2, RVA3, and RVA4 of the routing lines RM1, RM2, RM3, and RM4 may be disposed in the through holes TSV1, TSV2, TSV3, and TSV4. The through holes TSV1, TSV2, TSV3, and TSV4 may form connection paths of the routing lines RM1, RM2, RM3, and RM4 electrically connecting the driving part 100 to the terminals DTD, GTD1, GTD2, and PTD of the display part 200. In one or more embodiments, the through holes TSV1, TSV2, TSV3, and TSV4 of the second single crystal semiconductor substrate 210 may be formed through a through silicon via (TSV) process in which a hole that penetrates the wafer substrate is formed. Through the through holes TSV1, TSV2, TSV3, and TSV4 formed in the second single crystal semiconductor substrate 210, the display element layer 230 and the driving part 100 may be electrically connected to each other through the routing lines RM1, RM2, RM3, and RM4 without an additional wire.

A process of reducing the thickness of the second single crystal semiconductor substrate 210 may be performed after the driving part 100 is bonded onto the silicon wafer substrate. The second single crystal semiconductor substrate 210 may have a thickness greater than that of the wafer substrate on which a process for forming conductive layers is performed. In one or more embodiments, the thickness of the second single crystal semiconductor substrate 210 may be 100 μm or less, for example, in the range of 80 μm to 100 μm.

The pixel circuit 220 may be disposed on the second single crystal semiconductor substrate 210. The pixel circuit 220 may include a portion of the pixel circuit backplane EBP and the semiconductor backplane SBP.

A third semiconductor insulating film SINS3 may be disposed on the second single crystal semiconductor substrate 210. The third semiconductor insulating film SINS3 may be formed of silicon carbonitride (SiCN) and/or a silicon oxide (SiOx)-based inorganic film, but is not limited thereto.

A fourth semiconductor insulating film SINS4 may be disposed on the third semiconductor insulating film SINS3. The fourth semiconductor insulating film SINS4 may be formed of a silicon oxide (SiOx)-based inorganic film, but is not limited thereto.

Each of the plurality of contact electrodes CTE may be connected to any one of the gate electrode GE, the source region SA, and the drain region DA of each of the second transistors PTR2 through holes penetrating the third semiconductor insulating film SINS3 and the fourth semiconductor insulating layer SINS4. The plurality of contact electrodes CTE may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them.

The pixel circuit backplane EBP may include third to seventh interlayer insulating layers INS3, INS4, INS5, INS6, and INS7 and a plurality of connection conductive layers RMT. The connection conductive layer RMT may include wires electrically connected to the plurality of second transistors PTR2 formed on the second single crystal semiconductor substrate 210. The pixel circuit backplane EBP may include the plurality of scan lines GL1 and GL2, the data lines DL, and the plurality of terminals DTD, GTD1, GTD2, and PTD disposed in the display part 200.

The third interlayer insulating layer INS3 may be disposed on the plurality of contact electrodes CTE and the semiconductor insulating layers SINS3 and SINS4. The fourth interlayer insulating layer INS4 may be disposed on the third interlayer insulating layer INS3. The fifth interlayer insulating layer INS5, the sixth interlayer insulating layer INS6, and the seventh interlayer insulating layer INS7 may be disposed sequentially disposed on the fourth interlayer insulating layer INS4. The plurality of connection conductive layers RMT may be disposed between the third interlayer insulating layer INS3 to the seventh interlayer insulating layer INS7. Each of the third to seventh interlayer insulating layers INS3 to INS7 may be formed of silicon carbonitride (SiCN) and/or a silicon oxide (SiOx)-based inorganic film, but is not limited thereto. Although it is illustrated in the drawings that each of the third to seventh interlayer insulating layers INS3 to INS7 is formed as a single layer, the present disclosure is not limited thereto. Each of the third to seventh interlayer insulating layers INS3 to INS7 may have a structure in which one or more layers are stacked on top of each other, and may be disposed between the plurality of first to eighth conductive layers ML1 to ML8 as described above.

The connection conductive layer RMT may have a structure similar to the plurality of conductive layers ML1 to ML8 and the vias VA1 to VA8 of the driving circuit layer 120. The connection conductive layer RMT may include one or more conductive layers and vias disposed between them to form the terminals DTD, GTD1, GTD2, and PTD or the wires disposed in the display part 200. For example, the connection conductive layers RMT of the pixel circuit 220 disposed in the display area DAA may be electrically connected to the second transistor PTR2. The connection conductive layers RMT shown in the drawings may be connected to the plurality of second transistors PTR2 to form the pixel circuit of FIG. 6. The connection conductive layers RMT may serve as connection lines that connect the second transistor PTR2 to other circuit elements. In addition, in one or more embodiments, some of the connection conductive layers RMT disposed in the display area DAA of the pixel circuit 220 may be the scan lines GL1 and GL2, or the data line DL, or may serve as the terminals DTD, GTD1, GTD2, and PTD.

The pixel circuit 220 may include the plurality of terminals DTD, GTD1, GTD2, and STD disposed in the non-display area NA. The plurality of terminals DTD, GTD1, GTD2, and PTD may include a data terminal DTD electrically connected to the data line DL, gate terminals GTD1 and GTD2 connected to the scan lines GL1 and GL2, and a signal terminal STD. The plurality of terminals DTD, GTD1, GTD2, and STD may be connected to the conductive vias RVA1, RVA2, RVA3, and RVA4 of the routing lines in the through hole areas TSA1, TSA2, TSA3, and TSA4 of the non-display area NA.

The connection line layer 500 may be disposed on the bottom surface of the second single crystal semiconductor substrate 210. The connection line layer 500 may include an interlayer insulating layer RINS and the plurality of connection lines RML1, RML2, RML3, and RML4.

The interlayer insulating layer RINS may be disposed on the bottom surface of the second single crystal semiconductor substrate 210. The interlayer insulating layer RINS may be formed of a silicon carbon nitride (SiCN) and/or silicon oxide (SiOₓ)-based inorganic film, but is not limited thereto. In the drawing, the interlayer insulating layer RINS is illustrated as a single layer, but is not limited thereto and may have a structure in which one or more layers are stacked on top of each other, and they may be disposed between the connection lines RML1, RML2, RML3, and RML4.

The connection lines RML1, RML2, RML3, and RML4 may form the routing lines RM1, RM2, RM3, and RM4 together with the plurality of conductive vias RVA1, RVA2, RVA3, and RVA4. The connection lines RML1, RML2, RML3, and RML4 may include one or more conductive layers, and one or more vias connecting them to each other. The connection and structure of the connection lines RML1, RML2, RML3, and RML4 may be the same as described above for the conductive layers ML1 to ML8 and the vias VA1 to VA8. The connection lines RML1, RML2, RML3, and RML4 may be electrically connected to the pad signal terminal PTD, and the lines GL1, GL2, and DL disposed in the display part 200 through the conductive vias RVA1, RVA2, RVA3, and RVA4 disposed in the through holes TSV1, TSV2, TSV3, and TSV4 of the second single crystal semiconductor substrate 210, and may be electrically connected to the driving circuit layer 120 of the driving part 100.

According to one or more embodiments, the display part 200 of the display device 10 may include the first through hole TSV1, the second through hole TSV2, the third through hole TSV3, and the fourth through hole TSV4 that penetrate the second single crystal semiconductor substrate 210. The first to fourth through holes TSV1, TSV2, TSV3, and TSV4 may each be disposed in the non-display area NA. As described above, the first through hole TSV1 may be disposed in the first through hole area TSA1 located to the upper side of the display area DAA, and the second through hole TSV2 and the third through hole TSV3 may be disposed in the second through hole area TSA2 and the third through hole area TSA3 located to the left and right sides of the display area DAA, respectively. The fourth through hole TSV4 may be disposed in the fourth through hole area TSA4 located between the display area DAA and the pad area PDA.

The first conductive via RVA1 of the first routing line RM1 may be disposed in the first through hole TSV1. The first through hole TSV1 may penetrate the second single crystal semiconductor substrate 210, the semiconductor insulating layers SINS3 and SINS4, and the interlayer insulating layers INS3, INS4, and INS5 to extend from the bottom surface of the data terminal DTD to the bottom surface of the second single crystal semiconductor substrate 210. The first conductive via RVA1 may also be disposed from the bottom surface of the data terminal DTD to the bottom surface of the second single crystal semiconductor substrate 210 to be connected to each of the data terminal DTD and the first connection line RML1. The first connection line RML1 may be the data routing line RDL described above with reference to FIGS. 7-8. The first routing line RM1 may connect the data terminal DTD connected to the data line DL to the driving circuit layer 120 or the data driver 700 of the driving part 100.

The second conductive via RVA2 of the second routing line RM2 may be disposed in the second through hole TSV2. The second through hole TSV2 may penetrate the second single crystal semiconductor substrate 210, the semiconductor insulating layers SINS3 and SINS4, and the interlayer insulating layers INS3, INS4, and INS5 to extend from the bottom surface of the first gate terminal GTD1 to the bottom surface of the second single crystal semiconductor substrate 210. The second conductive via RVA2 may also be disposed from the bottom surface of the first gate terminal GTD1 to the bottom surface of the second single crystal semiconductor substrate 210 to be connected to each of the first gate terminal GTD1 and the second connection line RML2. The second connection line RML2 may be the first scan routing line GCL1 described above with reference to FIG. 8. The second routing line RM2 may connect the first gate terminal GTD1 connected to the first scan line GL1 to the driving circuit layer 120 or the scan driver 610 of the driving part 100.

The third conductive via RVA3 of the third routing line RM3 may be disposed in the third through hole TSV3. The third through hole TSV3 may penetrate the second single crystal semiconductor substrate 210, the semiconductor insulating layers SINS3 and SINS4, and the interlayer insulating layers INS3, INS4, and INS5 to extend from the bottom surface of the second gate terminal GTD2 to the bottom surface of the second single crystal semiconductor substrate 210. The third conductive via RVA3 may also be disposed from the bottom surface of the second gate terminal GTD2 to the bottom surface of the second single crystal semiconductor substrate 210 to be connected to each of the second gate terminal GTD2 and the third connection line RML3. The third connection line RML3 may be the second scan routing line GCL2 described above with reference to FIG. 8. The third routing line RM3 may connect the second gate terminal GTD2 connected to the second scan line GL2 to the driving circuit layer 120 or the emission driver 620 of the driving part 100.

The fourth conductive via RVA4 of the fourth routing line RM4 may be disposed in the fourth through hole TSV4. The fourth through hole TSV4 may penetrate the second single crystal semiconductor substrate 210, the semiconductor insulating layers SINS3 and SINS4, and the interlayer insulating layers INS3, INS4, and INS5 to extend from the bottom surface of the pad signal terminal PTD to the bottom surface of the second single crystal semiconductor substrate 210. The fourth conductive via RVA4 may also be disposed from the bottom surface of the pad signal terminal PTD to the bottom surface of the second single crystal semiconductor substrate 210 to be connected to each of the pad signal terminal PTD and the fourth connection line RML4. The fourth connection line RML4 may be the signal routing line SCL described above with reference to FIG. 8. The fourth routing line RM4 may connect the pad signal terminal PTD electrically connected to the circuit board 300 to the signal terminal STD of the driving part 100.

In the display device 10, the circuit units provided in the driving part 100 may be formed by a high-cost micro semiconductor process, and thus may be formed with a high integration density on the first single crystal semiconductor substrate 110 having a small area. The fabrication process of the driving part 100 may have a high yield per unit wafer substrate, and a circuit element (e.g., the first transistor) may have a small size, resulting in reduced power consumption. In addition, by disposing wires and the pixel circuit for light emission of the light emitting element in the display part 200, it may be possible to prevent the integration density of the first single crystal semiconductor substrate 110 from becoming too high. In addition, by optimizing the number of the through holes TSV1, TSV2, TSV3, and TSV4 in which the routing lines RM1, RM2, RM3, and RM4 connecting them are disposed, a space in which the through holes TSV1, TSV2, TSV3, and TSV4 having (e.g., requiring) a suitable diameter (e.g., a predetermined diameter) and separation distance are disposed may be reduced or minimized.

The display layer 230 may be disposed on the second single crystal semiconductor substrate 210 and the pixel circuit 220. The display layer 230 may include the display element layer EML, the encapsulation layer TFE, the adhesive layer ADL, the optical layer OPL, and the cover layer DCL. The display layer 230 may include light emitting elements electrically connected to the driving part 100 and emit light.

The display element layer EML may be disposed on the pixel circuit backplane EBP of the pixel circuit 220. The display element layer EML may include light emitting elements having the reflective electrode layer RL, eighth and ninth interlayer insulating layers INS8 and INS9, the electrode via VAP, the first electrode AND, the light emitting stack IL, a second electrode CAT, the pixel defining film PDL, and the plurality of trenches TRC.

The reflective electrode layer RL may be disposed on the seventh interlayer insulating layer INS7. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 12.

Each of the first reflective electrodes RL1 may be disposed on the seventh interlayer insulating layer INS7 and may be connected to a via penetrating the seventh interlayer insulating layer INS7. The first reflective electrodes RL1 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may include titanium nitride (TiN).

Each of the second reflective electrodes RL2 may be disposed on the first reflective electrode RL1. The second reflective electrodes RL2 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (AI).

Each of the third reflective electrodes RL3 may be disposed on the second reflective electrode RL2. The third reflective electrodes RL3 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

Because the second reflective electrode RL2 is an electrode that substantially reflects light from the light emitting elements, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å. However, in one or more other embodiments, the thickness of the second reflective electrode RL2 may be the same as the thickness of each of the first reflective electrode RL1, the third reflective electrode RL3, and the fourth reflective electrode RL4.

The eighth interlayer insulating layer INS8 may be disposed on the seventh interlayer insulating layer INS7. The eighth interlayer insulating layer INS8 may be disposed between the reflective electrode layers RL adjacent to each other. The eighth interlayer insulating layer INS8 may be disposed on the reflective electrode layer RL in the first sub-pixel SP1. The eighth interlayer insulating layer INS8 may be formed of a silicon oxide (SiOx)-based inorganic film, but is not limited thereto.

The ninth interlayer insulating layer INS9 may be disposed on the eighth interlayer insulating layer INS8 and the reflective electrode layer RL. The ninth interlayer insulating layer INS9 may be formed of a silicon oxide (SiOx)-based inorganic film, but is not limited thereto.

In at least one of the first sub-pixel SP1, the second sub-pixel SP2, or the third sub-pixel SP3, the eighth interlayer insulating layer INS8 and the ninth interlayer insulating layer INS9 may not be disposed under the first electrode AND in consideration of the resonance distance of the light emitted from the light emitting elements LE.

For example, the first electrode AND of the third sub-pixel SP3 may be directly disposed on the fourth reflective electrode RL4, and the first electrode AND of the third sub-pixel SP3 may not overlap the eighth interlayer insulating layer INS8 and the ninth interlayer insulating layer INS9. The first electrode AND of the second sub-pixel SP2 may be disposed on the ninth interlayer insulating layer INS9, and the ninth interlayer insulating layer INS9 may be directly disposed on the fourth reflective electrode RL4. That is, the first electrode AND of the second sub-pixel SP2 may not overlap the eighth interlayer insulating layer INS8. The first electrode AND of the first sub-pixel SP1 may be disposed on the ninth interlayer insulating layer INS9, and may overlap the eighth interlayer insulating layer INS8.

In one or more embodiments, the distance between the first electrode AND and the reflective electrode layer RL may be different in the first sub-pixel SP1, the second sub-pixel SP2, and the third sub-pixel SP3. In order to adjust the distance from the reflective electrode layer RL to the second electrode CAT according to the main wavelength of the light emitted from each of the first sub-pixel SP1, the second sub-pixel SP2, and the third sub-pixel SP3, the presence or absence of the eighth interlayer insulating layer INS8 and the ninth interlayer insulating layer INS9 may be set in each of the first sub-pixel SP1, the second sub-pixel SP2, and the third sub-pixel SP3. For example, in FIG. 12, the distance between the first electrode AND and the reflective electrode layer RL in the first sub-pixel SP1 may be greater than the distance between the first electrode AND and the reflective electrode layer RL in the second sub-pixel SP2 and the distance between the first electrode AND and the reflective electrode layer RL in the third sub-pixel SP3, and the distance between the first electrode AND and the reflective electrode layer RL in the second sub-pixel SP2 may be greater than the distance between the first electrode AND and the reflective electrode layer RL in the third sub-pixel SP3. However, the present disclosure is not limited thereto. The distance between the first electrode AND and the reflective electrode layer RL in each of the sub-pixels SP1, SP2, and SP3 may be variously modified and designed.

In addition, although the eighth interlayer insulating layer INS8 and the ninth interlayer insulating layer INS9 are illustrated in the drawing, a tenth interlayer insulating layer may be further disposed under the first electrode AND of the sub-pixel SP. In this case, the ninth interlayer insulating layer INS9 and the tenth interlayer insulating layer may be disposed under the first electrode AND of the second sub-pixel SP2, and the eighth interlayer insulating layer INS8, the ninth interlayer insulating layer INS9, and the tenth interlayer insulating layer may be disposed under the first electrode AND of the first sub-pixel SP1.

Each of the electrode vias VAP may be connected to the fourth reflective electrode RL4 exposed through the eighth interlayer insulating layer INS8 and/or the ninth interlayer insulating layer INS9 in the first sub-pixel SP1 and the second sub-pixel SP2. The electrode vias VAP may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. The thickness of the electrode via VAP in the second sub-pixel SP2 may be smaller than the thickness of the electrode via VAP in the first sub-pixel SP1.

The first electrode AND of each of the light emitting elements is disposed on the ninth interlayer insulating layer INS9 or the reflective electrode layer RL and may be connected to the electrode via VAP. The first electrode AND of each of the light emitting elements LE may be connected to the second transistor PTR2 through the electrode via VAP, the first to fourth reflective electrodes RL1 to RL4, the connection conductive layer RMT, and the contact electrode CTE. The first electrode AND of each of the light emitting elements may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. For example, the first electrode AND of each of the light emitting elements may be titanium nitride (TIN).

The pixel defining film PDL may be disposed on a part of the first electrode AND of each of the light emitting elements. The pixel defining film PDL may cover the edge of the first electrode AND of each of the light emitting elements. The pixel defining film PDL may serve to partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include the first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but are not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first inorganic encapsulation layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

In order to prevent the first inorganic encapsulation layer TFE1 from being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. In each of the plurality of trenches TRC, a part of the eighth interlayer insulating layer INS8 may be dug and the ninth interlayer insulating layer INS9 may be penetrated.

At least one trench TRC may be disposed between adjacent sub-pixels SP1, SP2, and SP3. FIGS. 12-14 illustrate that two trenches TRC are disposed between the adjacent sub-pixels SP1, SP2, and SP3, but the present disclosure is not limited thereto.

The light emitting stack IL may include a plurality of stacks. It is illustrated in the drawing that the light emitting stack IL has a three-tandem structure including a first light emitting stack IL1, a second light emitting stack IL2, and a third light emitting stack IL3, but the present disclosure is not limited thereto. For example, the light emitting stack IL may have a two-tandem structure including two light emitting stacks.

In the three-tandem structure, the light emitting stack IL may have a tandem structure including the plurality of light emitting stacks IL1, IL2, and IL3 that emit different lights. For example, the light emitting stack IL may include the first light emitting stack IL1 that emits light of the first color, the second light emitting stack IL2 that emits light of the third color, and the third light emitting stack IL3 that emits light of the second color. The first light emitting stack IL1, the second light emitting stack IL2, and the third light emitting stack IL3 may be sequentially stacked.

The first light emitting stack IL1 may have a structure in which a first hole transport layer, a first organic light emitting layer that emits light of the first color, and a first electron transport layer are sequentially stacked. The second light emitting stack IL2 may have a structure in which a second hole transport layer, a second organic light emitting layer that emits light of the third color, and a second electron transport layer are sequentially stacked. The third light emitting stack IL3 may have a structure in which a third hole transport layer, a third organic light emitting layer that emits light of the second color, and a third electron transport layer are sequentially stacked.

A first charge generation layer for supplying charges to the second light emitting stack IL2 and supplying electrons to the first light emitting stack IL1 may be disposed between the first light emitting stack IL1 and the second light emitting stack IL2. The first charge generation layer may include an N-type charge generation layer that supplies electrons to the first light emitting stack IL1 and a P-type charge generation layer that supplies holes to the second light emitting stack IL2. The N-type charge generation layer may include a dopant of a metal material.

A first charge generation layer for supplying charges to the third light emitting stack IL3 and supplying electrons to the second light emitting stack IL2 may be disposed between the second light emitting stack IL2, and the third light emitting stack IL3. The second charge generation layer may include an N-type charge generation layer that supplies electrons to the second light emitting stack IL2 and a P-type charge generation layer that supplies holes to the third light emitting stack IL3.

The first light emitting stack IL1 may be disposed on the first electrodes AND and the pixel defining film PDL, and may be disposed on the bottom surface of each trench TRC. Due to the trench TRC, the first light emitting stack IL1 may be cut off between adjacent sub-pixels SP1, SP2, and SP3. The second light emitting stack IL2 may be disposed on the first light emitting stack IL1. Due to the trench TRC, the second light emitting stack IL2 may be cut off between adjacent sub-pixels SP1, SP2, and SP3. A void or an empty space ESS may be disposed between the first light emitting stack IL1 and the second light emitting stack IL2. The third light emitting stack IL3 may be disposed on the second light emitting stack IL2. The third light emitting stack IL3 is not cut off by the trench TRC and may be disposed to cover the second light emitting stack IL2 in each of the trenches TRC. That is, in the three-tandem structure, each of the plurality of trenches TRC may be a structure for cutting off the first to second light emitting stacks IL1 and IL2, the first charge generation layer, and the second charge generation layer of the display element layer EML between the sub-pixels SP1, SP2, and SP3 adjacent to each other. In addition, in the two-tandem structure, each of the plurality of trenches TRC may be a structure for cutting off the charge generation layer and a lower light emitting stack disposed between the lower light emitting stack and an upper light emitting stack.

In order to stably cut off the first and second light emitting stacks IL1 and IL2 of the display element layer EML between adjacent sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third light emitting stacks IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining film PDL.

The number of the light emitting stacks IL1, IL2, and IL3 that emit different lights is not limited to that shown in the drawing. For example, the light emitting stack IL may include two light emitting stacks. In this case, one of the two light emitting stacks may be substantially the same as the first light emitting stack IL1, and the other may include a second hole transport layer, a second organic light emitting layer, a third organic light emitting layer, and a second electron transport layer. In this case, a charge generation layer for supplying electrons to one light emitting stack and supplying charges to the other light emitting stack may be disposed between the two light emitting stacks.

In addition, FIGS. 12-14 illustrate that the first to third light emitting stacks IL1, IL2, and IL3 are all disposed in the first emission area EA1, the second emission area EA2, and the third emission area EA3, but the present disclosure is not limited thereto. For example, the first light emitting stack IL1 may be disposed in the first emission area EA1, and may not be disposed in the second emission area EA2 and the third emission area EA3. Furthermore, the second light emitting stack IL2 may be disposed in the second emission area EA2 and may not be disposed in the first emission area EA1 and the third emission area EA3. Further, the third light emitting stack IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third light emitting stack IL3. The second electrode CAT may be disposed on the third light emitting stack IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), and/or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic encapsulation layer TFE1 and TFE3 to prevent oxygen and/or moisture from permeating into the display element layer EML. In addition, the encapsulation layer TFE may include at least one organic film to protect the display element layer EML from foreign substances such as dust. For example, the encapsulation layer TFE may include the first inorganic encapsulation layer TFE1, the organic encapsulation layer TFE2, and a second inorganic encapsulation layer TFE3.

The first inorganic encapsulation layer TFE1 may be disposed on the second electrode CAT, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed of multiple films in which one or more inorganic films of silicon nitride (SiNₓ), silicon oxynitride (SiOₓN_{y}), silicon oxide (SiOₓ), titanium oxide (TiOₓ), and/or aluminum oxide (AlOₓ) layers are alternately stacked. The organic encapsulation layer TFE2 may be a monomer. Alternatively, the organic encapsulation layer TFE2 may be an organic film such as acryl resin, epoxy resin, phenolic resin, polyamide resin, polyimide resin, and/or the like.

The adhesive layer ADL may be disposed on the encapsulation layer TFE. The adhesive layer ADL may be a layer for bonding the encapsulation layer TFE to a layer disposed thereon. The adhesive layer ADL may be a double-sided adhesive member. In addition, the adhesive layer ADL may be a transparent adhesive member such as a transparent adhesive or a transparent adhesive resin.

The optical layer OPL may include the color filter layer CFL, the plurality of lenses LNS, and a filling layer FIL. The color filter layer CFL may include the first to third color filters CF1, CF2, and CF3. The first to third color filters CF1, CF2, and CF3 may be disposed on the adhesive layer ADL.

The first color filter CF1 may overlap the first emission area EA1. The first color filter CF1 may transmit light of the first color, i.e., light of a red wavelength band. The red wavelength band may be approximately 600 nm to 750 nm. The first color filter CF1 may transmit light of the first color from among light emitted from the first emission area EA1.

The second color filter CF2 may overlap the second emission area EA2. The second color filter CF2 may transmit light of the second color, i.e., light of a green wavelength band. The green wavelength band may be approximately 480 nm to 560 nm. The second color filter CF2 may transmit light of the second color from among light emitted from the second emission area EA2.

The third color filter CF3 may overlap the third emission area EA3. The third color filter CF3 may transmit light of the third color, i.e., light of a blue wavelength band. The blue wavelength band may be approximately 370 nm to 460 nm. The third color filter CF3 may transmit light of the third color from among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, and/or polyimide resin.

The cover layer DCL may be disposed on the filling layer FIL. The cover layer DCL may be a glass substrate and/or a polymer resin. When the cover layer DCL is a glass substrate, it may be attached onto the filling layer FIL. In this case, the filling layer FIL may serve to bond the cover layer DCL. When the cover layer DCL is a glass substrate, it may serve as an encapsulation substrate. When the cover layer DCL is a polymer resin, it may be directly applied onto the filling layer FIL.

In one or more embodiments, the display part 200 may further include a polarizing plate disposed on the cover layer DCL. The polarizing plate may be disposed on one surface of the cover layer DCL. The polarizing plate may be a structure for preventing visibility degradation caused by reflection of external light. The polarizing plate may include a linear polarizing plate and a phase retardation film. For example, the phase retardation film may be a λ/4 plate (quarter-wave plate), but is not limited thereto. However, when visibility degradation caused by reflection of external light is sufficiently overcome by the first to third color filters CF1, CF2, and CF3, the polarizing plate may be omitted.

FIG. 15 is a diagram illustrating the relative disposition of pixels and through holes disposed in a display part of a display device according to one or more embodiments.

Referring to FIG. 15, each pixel PX of the display part 200 may include three sub-pixel portions PXS corresponding to the respective sub-pixels SP1, SP2, and SP3. The sub-pixel portion PXS may be one of three evenly divided regions from one pixel PX. The sub-pixel portion PXS may be a region allocated to each of the sub-pixels SP1, SP2, and SP3 included in one pixel PX, but may not be the same as the sub-pixel SP1, SP2, SP3. As described above, in the display part 200, the shape and disposition of the sub-pixels SP1, SP2 and SP3 or the emission areas EA1, EA2, and EA3 may vary according to the disposition and shape of the first electrode AND of the light emitting element or the trench TRC of the pixel defining film PDL in a plan view. The shape and disposition of the sub-pixels SP1, SP2, and SP3 may be designed based on three sub-pixel portions PXS included in one pixel PX, and the light emitting elements and the pixel circuit PXC disposed based on the sub-pixel portions PXS may be electrically connected.

For example, in the embodiment of FIG. 10, three sub-pixels SP1, SP2, and SP3 and three emission areas EA1, EA2, and EA3 may be disposed adjacent to each other in the first direction DR1 and the second direction DR2. Although the arrangement of the three sub-pixel portions PXS is different from the arrangement of the three sub-pixels SP1, SP2, and SP3, at least a part of each sub-pixel SP1, SP2, SP3 may overlap the area of the sub-pixel portion PXS. When one sub-pixel SP1, SP2, SP3 is designed with respect to the sub-pixel portion PXS and an overlapping area thereof exists, the first electrode AND or the reflective electrodes RL1, RL2, RL3, and RL4 may be disposed to cover the overlapping area. Accordingly, the pixel circuit PXC of the pixel circuit 220 designed with respect to the sub-pixel portions PXS may be electrically connected to the light emitting elements.

In the display area DAA, the sub-pixels SP1, SP2, and SP3 may not necessarily have an even arrangement according to the type of light emitted from each light emitting element or the type of light displayed from the emission areas EA1, EA2, and EA3. On the other hand, the sub-pixel portion PXS is one of the evenly divided regions from each pixel PX, and may have a constant arrangement throughout the display area DAA. Accordingly, when each of the sub-pixels SP1, SP2, and SP3 is connected to another element, for example, the pixel circuit PXC of the pixel circuit 220, the disposition of the connection conductive layer RMT may be easily designed based on the arrangement of the sub-pixel portions PXS rather than the arrangement of the sub-pixels SP1, SP2, and SP3.

According to one or more embodiments, the display part 200 may include the plurality of through holes TSV1, TSV2, TSV3, and TSV4, and each of them may be arranged along one direction. For example, the plurality of first through holes TSV1 may be arranged to be spaced (e.g., spaced apart) from each other in the first direction DR1 in the first through hole area TSA1, and the plurality of second through holes TSV2 may be arranged to be spaced (e.g., spaced apart) from each other in the second direction DR2 in the second through hole area TSA2. In one or more embodiments, the third through holes TSV3 may be arranged to be spaced (e.g., spaced apart) from each other in the second direction DR2 in the third through hole area TSA3, and the fourth through holes TSV4 may be arranged to be spaced (e.g., spaced apart) from each other in the first direction DR1 in the fourth through hole area TSA4.

Three sub-pixel portions PXS may be evenly disposed in one pixel PX, and three data lines DL, three first scan lines GL1, and two second scan lines GL2 may pass through one pixel PX.

The data lines DL may be disposed to respectively correspond to the sub-pixel portions PXS, and the first through holes TSV1 may also be disposed to respectively correspond to the sub-pixel portions PXS. When a region occupied by one pixel PX extends in the second direction DR2, three first through holes TSV1 may be arranged in the extension region of the pixel PX in the first through hole area TSA1.

Three first scan lines GL1 may be disposed to correspond to one pixel PX, and three second through holes TSV2 may also be disposed to correspond to one pixel PX. When the region occupied by one pixel PX extends in the first direction DR1, three second through holes TSV2 may be arranged in the extension region of the pixel PX in the second through hole area TSA2. In one or more embodiments, two second scan lines GL2 may be disposed to correspond to one pixel PX, and when the region occupied by one pixel PX extends in the first direction DR1, two third through holes TSV3 may be arranged in the extension region of the pixel PX in the third through hole area TSA3.

Accordingly, the diameters and separation distances of the plurality of first to third through holes TSV1, TSV2, and TSV3 may vary depending on the area of the region occupied by the pixel PX or a distance PXP between the adjacent pixels PX. For example, if the distance between the adjacent first to third through holes TSV1, TSV2, and TSV3 is greater than the distance PXP between the adjacent pixels PX, three or two through holes may not be disposed correspondingly in a region corresponding to one pixel PX. In this case, the area in which the through holes TSV1, TSV2, and TSV3 are disposed may become larger, and the data line DL and the scan lines GL1 and GL2 may have a shape bent toward a wide area instead of extending in one direction. That is, by designing the disposition of the through holes TSV1, TSV2, and TSV3 and a distance TVP between them based on the distance PXP between the pixels PX of the display part 200, a suitable number (e.g., a required number) of the through holes TSV1, TSV2, and TSV3 may be completely disposed to correspond to the region occupied by each pixel PX. Accordingly, the non-display area NA or dead space of the display part 200 may be reduced, and a micro-display device 10 may be implemented.

In one or more embodiments, the distance TVP between the centers of the plurality of first through holes TSV1 may be 62% or less, or 61.0328% or less of the distance PXP between the adjacent pixels PX. For example, in one or more embodiments in which the distance PXP between the pixels PX is 8.47 μm, the distance TVP between the centers of the adjacent first through holes TSV1 may be 5.16 μm or less. Similarly, the distance TVP between the centers of the adjacent second through holes TSV2 may also be 5.16 μm or less. The distance PXP between two pixels PX adjacent in the first direction DR1 and the second direction DR2 may be the same, and the distance between the first through holes TSV1 arranged along the first direction DR1 and the distance between the second through holes TSV2 arranged along the second direction DR2 may each be 62% or less, or 61.0328% or less of the distance PXP between the adjacent pixels PX.

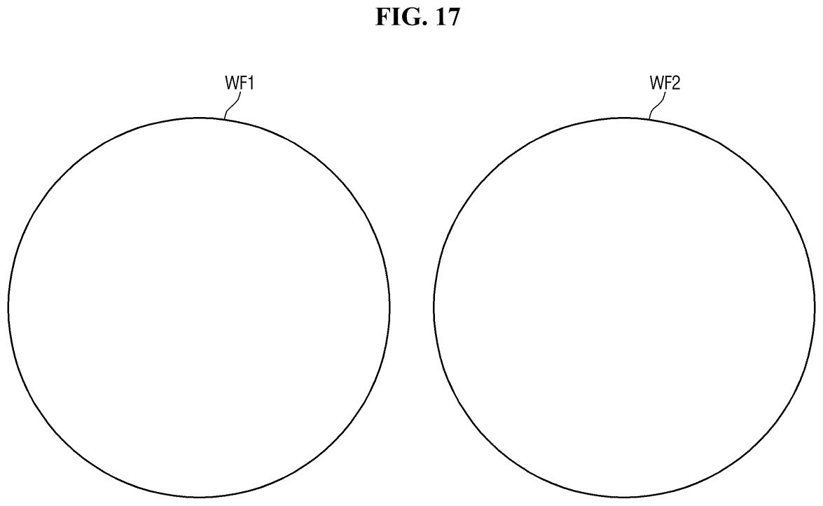

In the display device 10 according to one or more embodiments, optimized fabrication processes for the elements of the driving part 100 and for the light emitting elements of the display part 200 may be different from each other. In consideration of this, they may be formed on different wafers through separate processes capable of increasing fabrication yields. In particular, because the process of forming the driving circuit layer 120 included in the driving part 100 of the display device 10 is performed as a micro semiconductor process, the yield per unit area of a first wafer substrate WF1 (e.g., see FIG. 17) may be improved. In addition, in the process of forming the display part 200 of the display device 10, the space occupied by unnecessary elements other than the light emitting element can be reduced or minimized and a display device with a high resolution per unit area can be implemented.

Further, the display device 10 may have a structure in which the driving part 100 and the display part 200, which include different single crystal semiconductor substrates, are connected via the routing lines RM1, RM2, RM3, and RM4. The through holes TSV1, TSV2, TSV3, and TSV4 in which the conductive vias RVA1, RVA2, RVA3, and RVA4 of the routing lines RM1, RM2, RM3, and RM4 are disposed may be disposed to be spaced (e.g., spaced apart) from each other based on the distance PXP between the pixels PX of the display part 200. The plurality of through holes TSV1, TSV2, TSV3, and TSV4 may be disposed in pairs to correspond to the region occupied by each pixel PX, and the dead space or a separate space for the through holes TSV1, TSV2, TSV3, and TSV4 or the signal lines may be reduced.

Hereinafter, a method for fabrication of the display device 10 will be described with reference to other drawings.

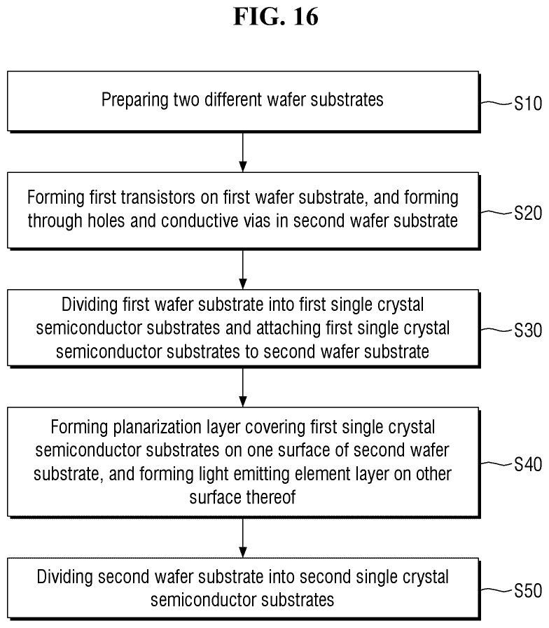

FIG. 16 is a flowchart illustrating a method for fabrication of the display device according to one or more embodiments.

Referring to FIG. 16, a method for fabrication of the display device 10 according to one or more embodiments may include preparing two different wafer substrates (step S10), forming first transistors on a first wafer substrate and forming through holes and conductive vias in a second wafer substrate (step S20), dividing the first wafer substrate into first single crystal semiconductor substrates and attaching the first single crystal semiconductor substrates to the second wafer substrate (step S30), forming a planarization layer that covers the first single crystal semiconductor substrates on one surface of the second wafer substrate and forming a light emitting element layer on the other surface thereof (step S40), and dividing the second wafer substrate into second single crystal semiconductor substrates (step S50).

The method for fabrication of the display device 10 may include performing processes suitable for forming the components of the display device 10 respectively on two different wafer substrates, and bonding them to each other. The driving part 100 including the driving circuit layer 120 may be fabricated by forming fine-sized elements on the first wafer substrate and may be bonded to the second wafer substrate, and then the display layer 230 including the display element layer EML may be formed to fabricate the display part 200. Accordingly, on the first wafer substrate, fine elements may be formed at a high integration density, thereby improving fabrication yield and reducing fabrication cost, and on the second wafer substrate, circuits other than the light emitting elements are not disposed, thereby reducing an unnecessary area and enabling the implementation of a high-resolution display device.

FIGS. 17-22 are diagrams sequentially showing a fabrication process of a display device according to one or more embodiments. FIGS. 17-22 schematically show a process in which two different wafer substrates WF1 and WF2 are bonded to each other and divided.

Referring to FIG. 17, a first wafer substrate WF1 and a second wafer substrate WF2 are prepared (step S10). Each of the first wafer substrate WF1 and the second wafer substrate WF2 may be a silicon substrate, a germanium substrate, and/or a silicon-germanium substrate. The first single crystal semiconductor substrate 110 and the second single crystal semiconductor substrate 210 may be substrates doped with the first type impurity. A plurality of well regions may be disposed on the top surface of the first single crystal semiconductor substrate 110. They may be mother substrates of the first single crystal semiconductor substrate 110 and the second single crystal semiconductor substrate 210 of the display device 10.

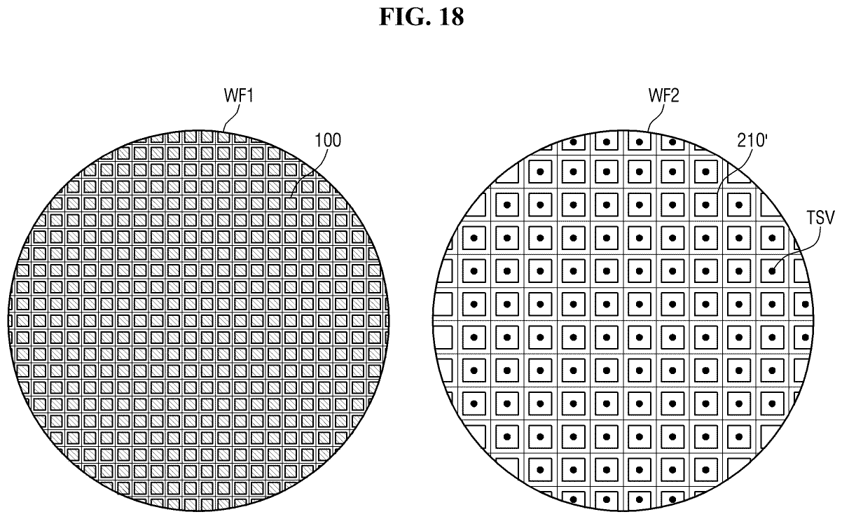

Referring to FIG. 18, the driving part 100 is fabricated by forming the plurality of first transistors PTR1 and the driving circuit layer 120 on one surface of the first wafer substrate WF1. The plurality of second transistors PTR2 and the pixel circuit 220 is formed on one surface of the second wafer substrate WF2, and a plurality of through holes TSV penetrating the second wafer substrate WF2 and conductive vias RVA disposed therein are formed to form a temporary single crystal semiconductor substrate 210′.

The process of forming the plurality of first transistors PTR1 and the driving circuit layer 120 on the first wafer substrate WF1 may be a micro semiconductor process. On the other hand, the process of forming the second transistors PTR2 on the second wafer substrate WF2 and the process of forming the through holes TSV may be a process having a larger line width than the semiconductor process performed on the first wafer substrate WF1. Although the first wafer substrate WF1 and the second wafer substrate WF2 have the same area, the driving part 100 and the temporary single crystal semiconductor substrate 210′ formed in this process may have different areas. Accordingly, the number of the driving parts 100 formed on the first wafer substrate WF1 may be greater than the number of the temporary single crystal semiconductor substrates 210′ formed on the second wafer substrate WF2. The process of fabricating the driving part 100 on the first wafer substrate WF1 is an expensive semiconductor process, but may have a relatively high yield.

The method for fabrication of the display device 10 may fabricate a display device in which a circuit unit necessary for driving the light emitting element of the display part 200 is disposed in the driving circuit layer 120 of the driving part 100. In the process of forming the driving circuit layer 120 on the first wafer substrate WF1, the driving circuit layer 120 may include the driving circuit 400, the gate driver 600, and the data driver 700. On the other hand, the pixel circuit 220 may be formed on the second wafer substrate WF2.

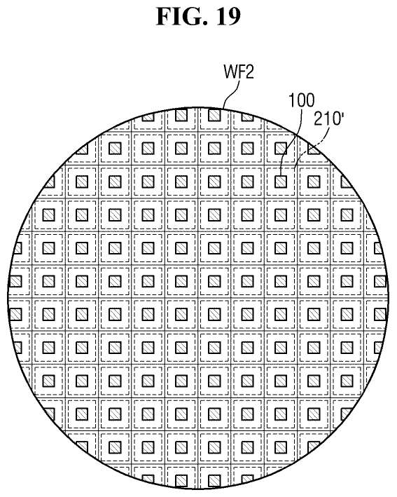

Next, referring to FIG. 19, the first wafer substrate WF1 is divided into a plurality of first single crystal semiconductor substrates 110, and the first single crystal semiconductor substrates 110 are attached to the bottom surface of the second wafer substrate WF2. The first wafer substrate WF1 may be divided into the plurality of first single crystal semiconductor substrates 110 on which the driving circuit layers 120 are formed. In one or more embodiments, the driving circuit layer 120 disposed on the first single crystal semiconductor substrate 110 may be bonded to the bottom surface of the temporary single crystal semiconductor substrate 210′. The process of bonding the first single crystal semiconductor substrate 110 to the bottom surface of the second wafer substrate WF2 may not be a bonding between two different wafer substrates, but rather a process of separating the first single crystal semiconductor substrate 110 from the first wafer substrate WF1 and then bonding it to the second wafer substrate WF2. The plurality of first single crystal semiconductor substrates 110 may be bonded correspondingly to the plurality of temporary single crystal semiconductor substrates 210′ formed on the second wafer substrate WF2.

The process of bonding the first single crystal semiconductor substrate 110 to the second wafer substrate WF2 may be performed under a higher temperature condition than a process of forming the light emitting element layer to be described later. According to one or more embodiments, the process of bonding the first single crystal semiconductor substrate 110 to the second wafer substrate WF2 may be performed prior to the process of forming the display element layer EML including the light emitting element on the second wafer substrate WF2. The method for fabrication of the display device 10 may not be a method of respectively fabricating the driving part 100 including the first single crystal semiconductor substrate 110 and the display part 200 including the second single crystal semiconductor substrate 210, and bonding them to each other. The method for fabrication of the display device 10 may involve a process of dividing the first wafer substrate WF1 into the driving parts 100 and bonding them to the second wafer substrate WF2 on which the light emitting elements are not formed.

In one or more embodiments, prior to performing the bonding process of FIG. 19, the connection line layer 500 (e.g., see FIG. 7) may be formed on the temporary single crystal semiconductor substrate 210′. The connection line layer 500 may be formed on the bottom surface of the second wafer substrate WF2, and the first single crystal semiconductor substrate 110 may be attached to the bottom surface of the second wafer substrate WF2 on which the connection line layer 500 is formed. Accordingly, the driving circuit layer 120 formed on the first single crystal semiconductor substrate 110 may be electrically connected to the connection line layer 500. However, the present disclosure is not limited thereto. The first single crystal semiconductor substrate 110 may be attached to the top surface of the second wafer substrate WF2 on which the connection line layer 500 is not formed. In this case, a planarization layer 910 to be described later may be formed on the top surface of the second wafer substrate WF2, and the display element layer EML may be formed on the top surface of the connection line layer 500 or on the bottom surface of the second wafer substrate WF2.

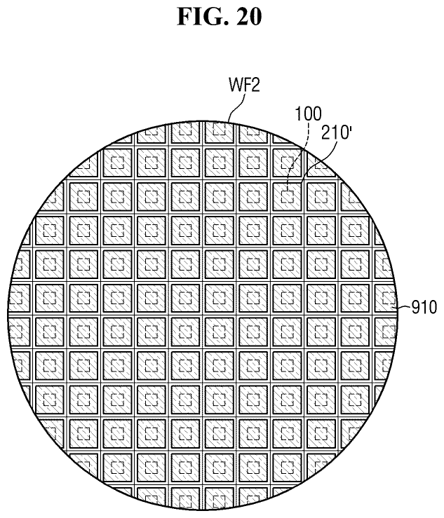

Next, referring to FIG. 20, the planarization layer 910 is formed on the bottom surface of the second wafer substrate WF2. The planarization layer 910 may flatten a step caused by the plurality of first single crystal semiconductor substrates 110 disposed on the bottom surface of the second wafer substrate WF2. As the planarization layer 910 is disposed, subsequent processes may be smoothly performed on the top surface of the second wafer substrate WF2. When the second wafer substrate WF2 is divided, the planarization layer 910 may be divided together to form the passivation layer 900 of the display device 10.

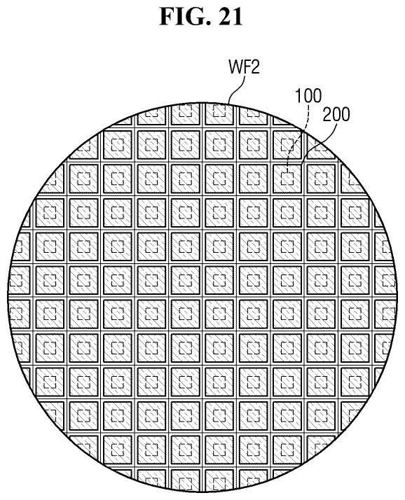

Next, referring to FIG. 21, the display element layer EML is formed on the top surface of the second wafer substrate WF2, which is opposite to the bottom surface where the driving part 100 is attached, to form the display part 200. The process of forming the display element layer EML may be performed by a process different from the semiconductor process of forming the driving circuit layer 120 on the first wafer substrate WF1. For example, the process of forming the display element layer EML may be performed by a semiconductor process having a relatively large line width, and may be a process resulting in (e.g., requiring) relatively low cost compared to the process of forming the driving circuit layer 120.

In the process of forming the display element layer EML, the plurality of light emitting elements of the display element layer EML may be electrically connected to the second transistors PTR2 formed on the second single crystal semiconductor substrate 210. The plurality of terminals DTD, GTD1, GTD2, and PTD of the display element layer EML may be respectively electrically connected to the conductive vias formed in the through holes TSV and the connection lines of the connection line layer 500, and may be electrically connected to the driving circuit layer 120 of the driving part 100 through the conductive vias and the connection lines. Further, in this process, the display layer 230 including the display element layer EML, the encapsulation layer TFE, the optical layer OPL, and the like may be formed. As the display layer 230 is formed on the second wafer substrate WF2, the display part 200 including the display layer 230 may be formed.

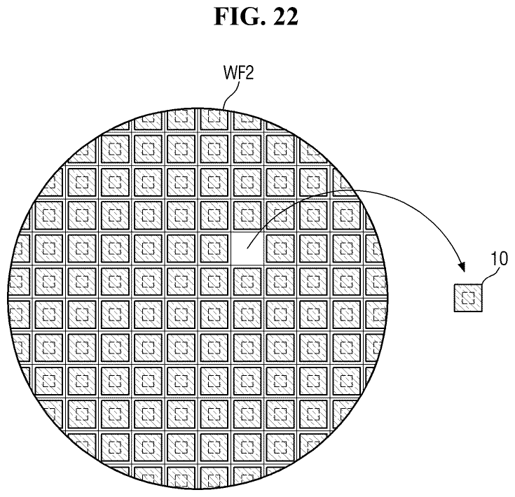

Next, referring to FIG. 22, the second wafer substrate WF2 may be divided into the second single crystal semiconductor substrates 210 on which the display element layers EML are formed. The display layer 230 including the display element layer EML may be formed on the top surface of the divided second single crystal semiconductor substrate 210, and the connection line layer 500, the first single crystal semiconductor substrate 110, and the passivation layer 900 may be attached to the bottom surface thereof. Next, in one or more embodiments, the display device 10 may be fabricated by attaching the circuit board 300 to one surface of the display part 200.

In the method for fabrication of the display device 10 according to one or more embodiments, a process of forming elements of a circuit unit and a process of forming the light emitting elements may be performed on different wafer substrates WF1 and WF2, respectively. In the display device 10, the elements of the circuit unit and the light emitting elements may have different optimized fabrication processes, and in consideration of this, they may be formed through separate processes that can increase fabrication yield on different wafer substrates. In particular, because the process of forming the driving circuit layer 120 included in the driving part 100 of the display device 10 is performed as a micro semiconductor process, the yield per unit area of the first wafer substrate WF1 may be improved. In addition, in the process of forming the display part 200 of the display device 10, the space occupied by unnecessary elements other than the light emitting element can be reduced or minimized and a display device with a high resolution per unit area can be implemented.

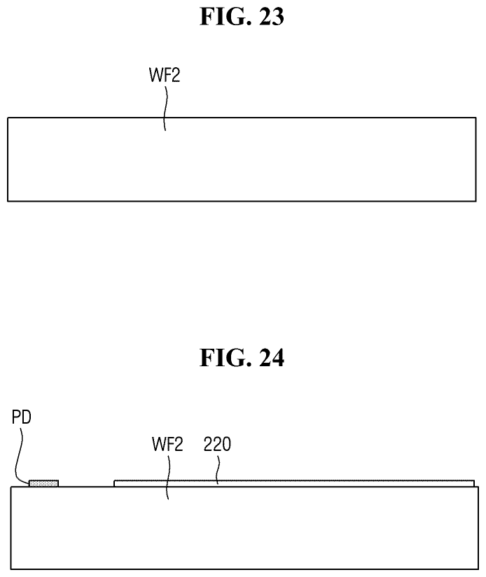

FIGS. 23-34 are cross-sectional views sequentially illustrating a fabrication process of a display device according to one or more embodiments. FIGS. 23-34 illustrate in more detail the process of forming the through holes TSV1, TSV2, TSV3, and TSV4 of the display part 200 and the routing lines RM1, RM2, RM3, and RM4 and connecting them to the driving part 100. FIGS. 23-34 omit processes of forming the driving part 100 on the first wafer substrate WF1 and dividing it.

Referring to FIGS. 23 and 24, the second wafer substrate WF2 is prepared, and the pixel circuit 220 and the pads PD are formed on one surface of the second wafer substrate WF2. The pixel circuit 220 may include the semiconductor backplane SBP and the pixel circuit backplane EBP described above with reference to FIGS. 12-14. The plurality of second transistors PTR2 are formed on the second wafer substrate WF2, and the pixel circuit 220 may include the plurality of insulating layers, the connection conductive layer RMT connected to the second transistors PTR2, and the plurality of terminals DTD, GTD1, GTD2, and PTD.

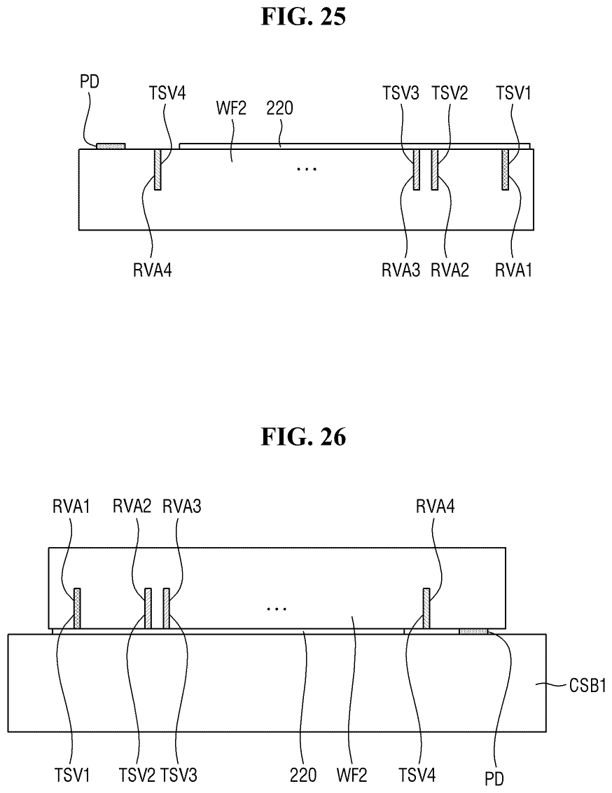

Referring to FIG. 25, the plurality of through holes TSV1, TSV2, TSV3, and TSV4 penetrating a portion of the second wafer substrate WF2 on which the pixel circuit 220 is formed, and the conductive vias RVA1, RVA2, RVA3, and RVA4 disposed in the through holes TSV1, TSV2, TSV3, and TSV4 are formed. The plurality of through holes TSV1, TSV2, TSV3, and TSV4 may be disposed to be spaced (e.g., spaced apart) from each other in a region of the second wafer substrate WF2 corresponding to the non-display area NA of the display part 200. The first through holes TSV1 may be disposed in the first through hole area TSA1 located to the upper side of the display area DAA, and the second through holes TSV2 and the third through holes TSV3 may be disposed in the second through hole area TSA2 and the third through hole area TSA3 located to the left and right sides of the display area DAA, respectively. The fourth through holes TSV4 may be disposed in the fourth through hole area TSA4 located between the display area DAA and the pad area PDA.

The plurality of first conductive vias RVA1 may be formed to respectively fill the first through holes TSV1, and the plurality of second conductive vias RVA2 may be formed to respectively fill the second through holes TSV2. The plurality of third conductive vias RVA3 may be formed to respectively fill the third through holes TSV3, and the plurality of fourth conductive vias RVA4 may be formed to respectively fill the fourth through holes TSV4. The first conductive vias RVA1 may be connected to the data terminal DTD of the pixel circuit 220, the second conductive vias RVA2 may be connected to the first gate terminal GTD1, and the third conductive vias RVA3 may be connected to the second gate terminal GTD2. The fourth conductive via RVA4 may be connected to the pad signal terminal PTD.

The depths of the through holes TSV1, TSV2, TSV3, and TSV4 may be smaller than the thickness of the second wafer substrate WF2. As will be described later, a process of reducing the thickness of the second wafer substrate WF2 may be performed. In the process, the through holes TSV1, TSV2, TSV3, and TSV4 may penetrate the second wafer substrate WF2 whose thickness has been reduced.

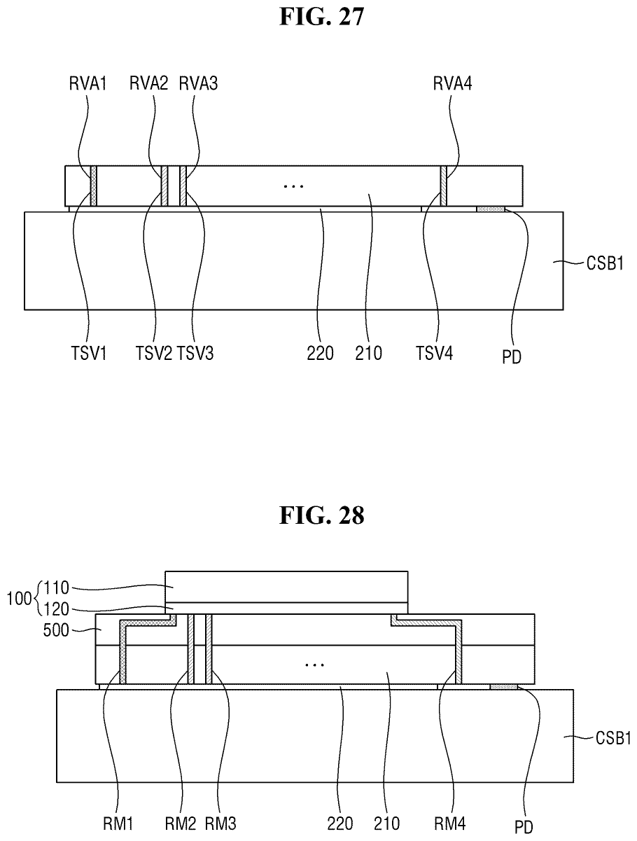

Referring to FIGS. 26 and 27, the second wafer substrate WF2 is moved onto a first carrier substrate CSB1, and then the thickness of the second wafer substrate WF2 is reduced, thereby forming the second single crystal semiconductor substrate 210. The first carrier substrate CSB1 may be attached to one surface of the second wafer substrate WF2 on which the through holes TSV1, TSV2, TSV3, and TSV4 are formed, for example, the top surface of the second wafer substrate WF2. The second wafer substrate WF2 may be turned over so that the other surface or bottom surface on which the through holes TSV1, TSV2, TSV3, and TSV4 are not formed faces upward, and the process of reducing the thickness of the second wafer substrate WF2 may be performed. In one or more embodiments, the thickness of the second wafer substrate WF2 may be reduced to be 100 μm or less, for example, in a range of 80 μm to 100 μm. After this process is performed, the plurality of through holes TSV1, TSV2, TSV3, and TSV4 may completely penetrate the second single crystal semiconductor substrate 210, and the plurality of conductive vias RVA1, RVA2, RVA3, and RVA4 may be exposed from the top and bottom surfaces of the second single crystal semiconductor substrate 210.

Referring to FIG. 28, the connection line layer 500 including connection lines is formed on one surface of the second single crystal semiconductor substrate 210, which is not in contact with the first carrier substrate CSB1, for example, the bottom surface thereof. The connection line layer 500 may include the interlayer insulating layer and the plurality of connection lines, and each of the connection lines may correspond to a different conductive via RVA1, RVA2, RVA3, RVA4. The first conductive via RVA1 and the connection line may form the first routing line RM1, and the second conductive via RVA2 and the connection line may form the second routing line RM2. The third conductive via RVA3 and the connection line may form the third routing line RM3, and the fourth conductive via RVA4 and the connection line may form the fourth routing line RM4.

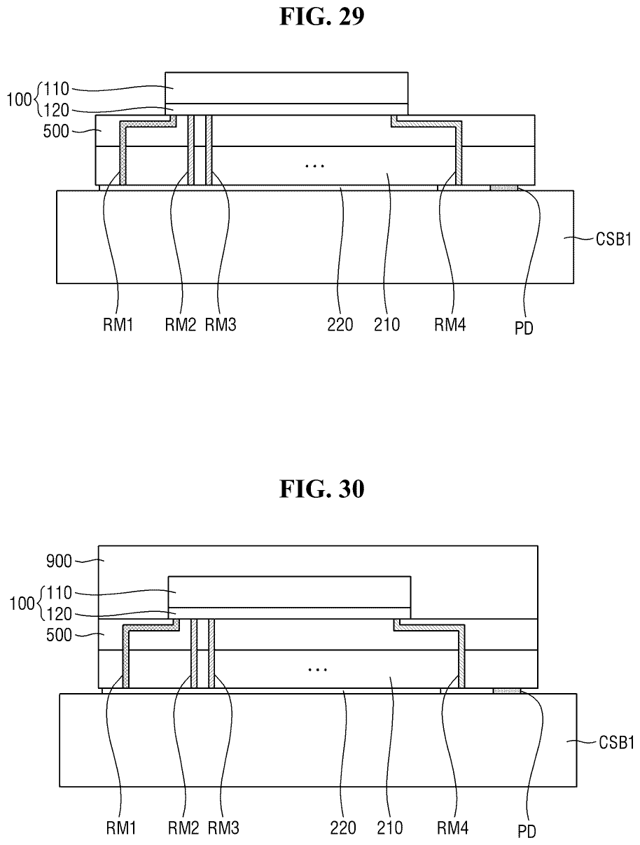

Referring to FIG. 29, the driving part 100 including the first single crystal semiconductor substrate 110 and the driving circuit layer 120 is attached onto the connection line layer 500. The driving part 100 may be formed on the first wafer substrate WF1 and divided therefrom, and may have a smaller area than that of the second single crystal semiconductor substrate 210. The plurality of routing lines RM1, RM2, RM3, and RM4 may be connected to the data driver 700, the gate driver 600, and the signal terminal STD of the driving part 100.

Referring to FIG. 30, the passivation layer 900 or a planarization layer is formed to cover the driving part 100. The passivation layer 900 may compensate for a step caused by the driving part 100 and protect the driving part 100.

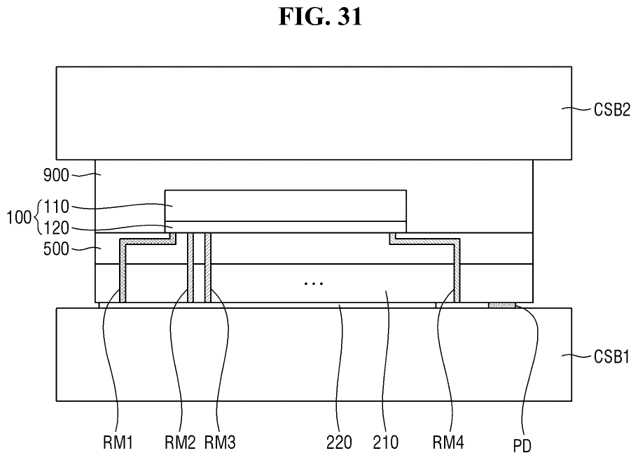

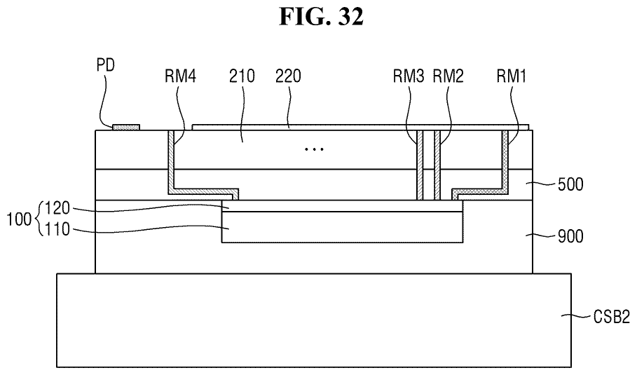

Referring to FIGS. 31 and 32, a second carrier substrate CSB2 is attached onto one surface of the passivation layer 900, it is turned over, and then the first carrier substrate CSB1 is removed. If the first carrier substrate CSB1 is removed, the top surface of the second single crystal semiconductor substrate 210 may be exposed.

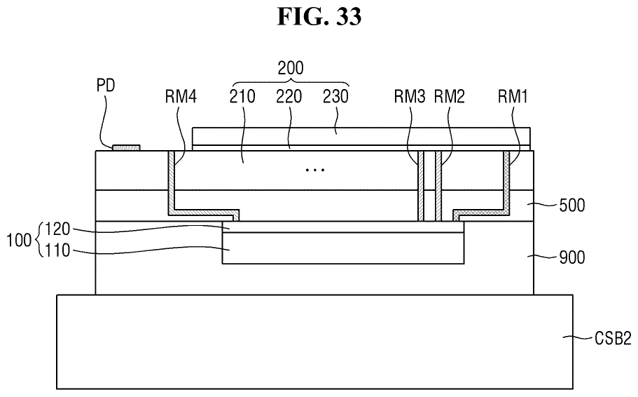

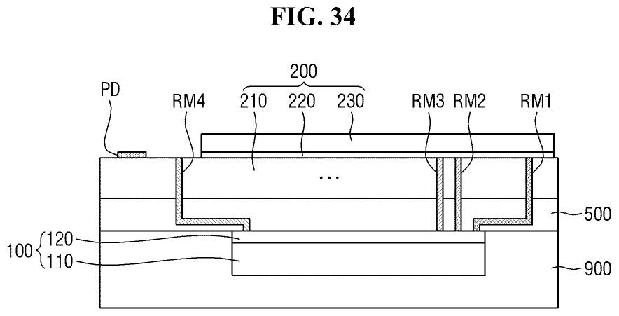

Referring to FIGS. 33 and 34, the display layer 230 is formed on the pixel circuit 220 to form the display part 200, and the second carrier substrate CSB2 is removed. In the process of forming the display layer 230, the light emitting elements of the display element layer EML may be electrically connected to the second transistors PTR2 of the second single crystal semiconductor substrate 210. The pads PD may be electrically connected to the signal terminal STD of the driving part 100 via the fourth routing line RM4.

Next, in one or more embodiments, the circuit board 300 may be attached onto the pad PD of the display part 200, thereby fabricating the display device 10.

Hereinafter, various embodiments of the display device 10 will be described with reference to other drawings.

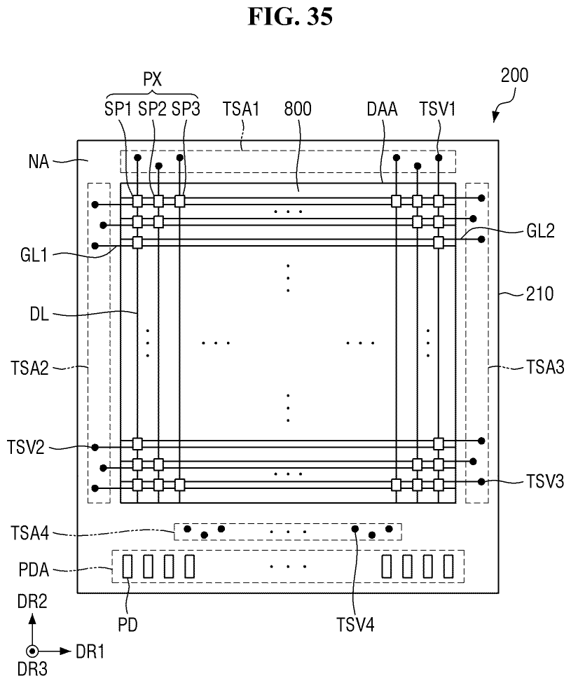

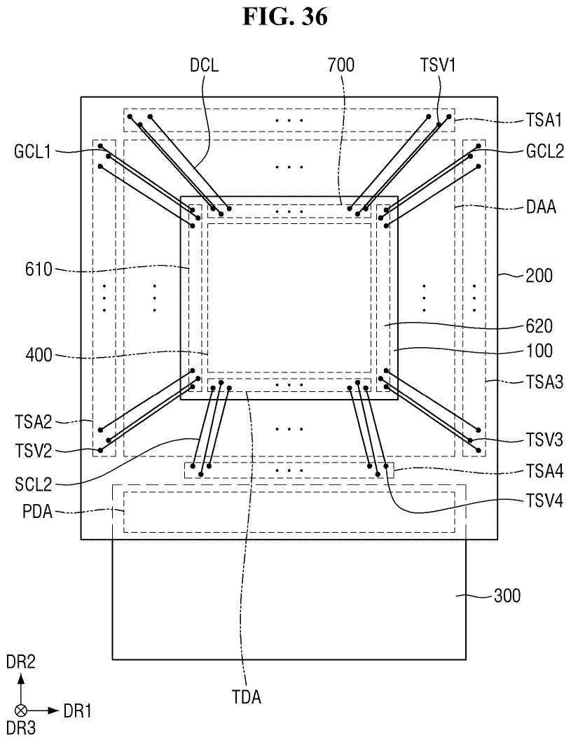

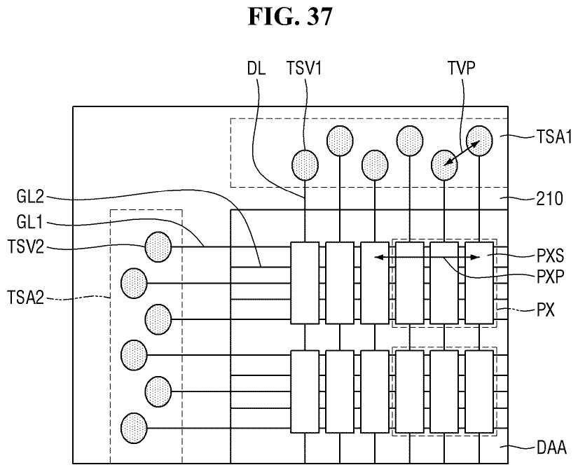

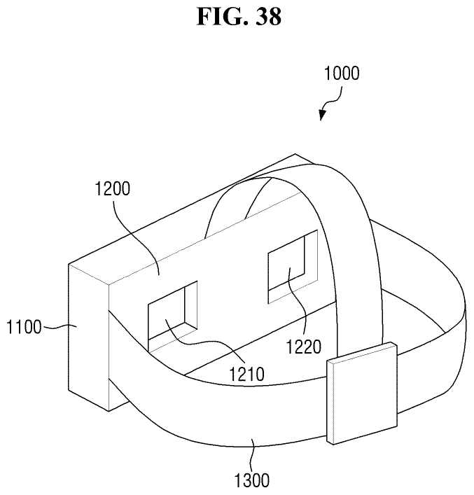

FIG. 35 is a plan view illustrating the disposition of a plurality of wires disposed in a display part of a display device according to one or more embodiments. FIG. 36 is a schematic diagram showing the rear surface of the display device of FIG. 35. FIG. 37 is a diagram illustrating the relative disposition of through holes and pixels disposed in a display part of the display device of FIG. 35.

Referring to FIGS. 35-37, the plurality of through holes TSV1 and TSV2 formed in the display part 200 may be spaced (e.g., spaced apart) from other adjacent through holes TSV1 and TSV2 in the diagonal direction. As described above, the plurality of through holes may be formed in one pixel PX to correspond thereto. For example, three first through holes TSV1 and three second through holes TSV2 may be formed to correspond to one pixel PX. In one or more embodiments, two third through holes TSV3 may also be formed to correspond to one pixel PX. If the distance between the adjacent through holes TSV1, TSV2, and TSV3 is too small, interference between the conductive vias disposed in the through holes TSV1, TSV2, and TSV3 may occur. If the distance between the through holes TSV1, TSV2, and TSV3 corresponding to one pixel PX is too large, a suitable number (e.g., a required number) of the through holes TSV1, TSV2, and TSV3 may not be disposed in a region corresponding to one pixel PX. In this case, a separate routing line may connect (e.g., may be required to connect) the through holes TSV1, TSV2, and TSV3 or the conductive vias disposed in the through holes TSV1, TSV2, and TSV3 to the signal lines DL, GL1 and GL2. That is, by designing the disposition of the through holes TSV1, TSV2, and TSV3 and the distance TVP between them based on the distance PXP between the pixels PX of the display part 200, the plurality of through holes TSV1, TSV2, and TSV3 may be disposed in a region corresponding to each pixel PX. Accordingly, the non-display area NA or dead space of the display part 200 may be reduced, and a micro-display device 10 may be implemented.

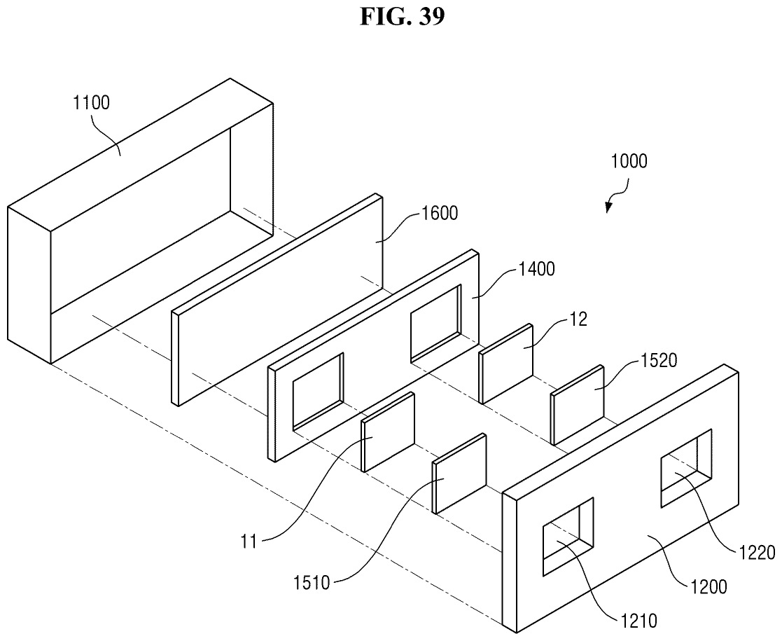

FIG. 38 is a perspective view illustrating a head mounted display device according to one or more embodiments. FIG. 39 is an exploded perspective view showing an example of the head mounted display device of FIG. 38.

Referring to FIGS. 38 and 39, a head mounted display device 1000 according to one or more embodiments includes a first display device 11, a second display device 12, a display device housing 1100, a housing cover 1200, a first eyepiece 1210, a second eyepiece 1220, a head mounted band 1300, a middle frame 1400, a first optical member 1510, a second optical member 1520, a control circuit board 1600, and a connector.

The first display device 11 provides an image to a user's left eye, and the second display device 12 provides an image to a user's right eye. Because each of the first display device 11 and the second display device 12 is substantially the same as the display device 10 described in conjunction with FIG. 1, the description of the first display device 11 and the second display device 12 will be omitted.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1400 may be disposed between the first display device 11 and the control circuit board 1600 and between the second display device 12 and the control circuit board 1600. The middle frame 1400 serves to support and fix the first display device 11, the second display device 12, and the control circuit board 1600.

The control circuit board 1600 may be disposed between the middle frame 1400 and the display device housing 1100. The control circuit board 1600 may be connected to the first display device 11 and the second display device 12 through the connector. The control circuit board 1600 may convert an image source inputted from the outside into the digital video data DATA, and may transmit the digital video data DATA to the first display device 11 and the second display device 12 through the connector.

The control circuit board 1600 may transmit the digital video data DATA corresponding to a left-eye image optimized for the user's left eye to the first display device 11, and may transmit the digital video data DATA corresponding to a right-eye image optimized for the user's right eye to the second display device 12. Alternatively, the control circuit board 1600 may transmit the same digital video data DATA to the first display device 11 and the second display device 12.

The display device housing 1100 serves to accommodate the first display device 11, the second display device 12, the middle frame 1400, the first optical member 1510, the second optical member 1520, the control circuit board 1600, and the connector. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. It is illustrated in the drawing that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 11 and the first optical member 1510, and the second eyepiece 1220 may be aligned with the second display device 12 and the second optical member 1520. Accordingly, the user may view the image of the first display device 11 magnified as a virtual image by the first optical member 1510 through the first eyepiece 1210, and may view the image of the second display device 12 magnified as a virtual image by the second optical member 1520 through the second eyepiece 1220.

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1200 is implemented to be lightweight and compact, the head mounted display device 1000 may be provided with an eyeglass frame instead of the head mounted band 1300.

In addition, the head mounted display device 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

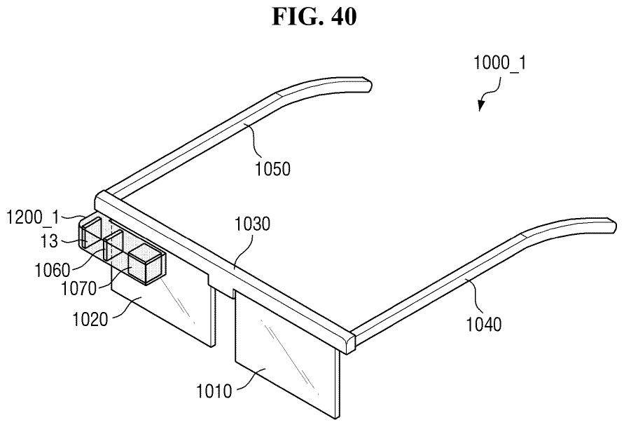

FIG. 40 is a perspective view illustrating a head mounted display device according to one or more embodiments.

Referring to FIG. 40, a head mounted display device 1000_1 according to one or more embodiments may be an eyeglasses-type display device in which a display device housing 1200_1 is implemented in a lightweight and compact manner. The head mounted display device 1000_1 according to one or more embodiments may include a display device 13, a left eye lens 1010, a right eye lens 1020, a support frame 1030, temples 1040 and 1050, an optical member 1060, an optical path changing member 1070, and the display device housing 1200_1.

The display device housing 1200_1 may include the display device 13, the optical member 1060, and the optical path changing member 1070. An image displayed on the display device 13 may be magnified by the optical member 1060, and the optical path may be changed by the optical path changing member 1070 to provide the image to the user's right eye through the right eye lens 1020. As a result, the user may view an augmented reality image, through the right eye, in which a virtual image displayed on the display device 13 and a real image seen through the right eye lens 1020 are combined.

It is illustrated in the drawing that the display device housing 1200_1 is disposed at the right end of the support frame 1030, but the present disclosure is not limited thereto. For example, the display device housing 1200_1 may be disposed on the left end of the support frame 1030, and in this case, the image of the display device 13 may be provided to the user's left eye. Alternatively, the display device housing 1200_1 may be disposed on both the left and right ends of the support frame 1030, and in this case, the user may view the image displayed on the display device 13 through both the left and right eyes.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a first single crystal semiconductor substrate at which a plurality of first transistors is located;
a second single crystal semiconductor substrate on the first single crystal semiconductor substrate, and at which a plurality of second transistors is located; and
a connection line layer between the first single crystal semiconductor substrate and the second single crystal semiconductor substrate,
wherein the second single crystal semiconductor substrate includes a display area where a plurality of sub-pixels is located, each of the plurality of sub-pixels comprising a light emitting element, a plurality of first through holes in a non-display area around the display area, and in which a first conductive via connected to a plurality of data lines extending in a first direction is located, and a plurality of second through holes in the non-display area, and in which a second conductive via connected to a plurality of first scan lines extending in a second direction is located, and
wherein the connection line layer comprises a first connection line connecting the first conductive via to a data driver on the first single crystal semiconductor substrate, and a second connection line connecting the second conductive via to a scan driver on the first single crystal semiconductor substrate.

2. The display device of claim 1, wherein the first through holes are spaced from each other, and the second through holes are spaced from each other.

3. The display device of claim 2, wherein the plurality of first through holes and the plurality of second through holes are each spaced from the other adjacent first through holes or the other adjacent second through holes in a diagonal direction.

4. The display device of claim 1, wherein in the display area, a plurality of pixels comprising three sub-pixels are arranged, and
wherein three first through holes are in a region occupied by one pixel extending in one direction toward the non-display area.

5. The display device of claim 4, wherein the pixel comprises three sub-pixel portions respectively corresponding to the plurality of sub-pixels, and
wherein a distance between the first through holes is 61.0328% or less of a distance between corresponding sub-pixel portions in neighboring pixels from among the plurality of pixels.

6. The display device of claim 1, wherein the plurality of first through holes and the plurality of second through holes do not overlap the first single crystal semiconductor substrate, and
wherein each of the first connection lines and the second connection lines has at least a portion overlapping the first single crystal semiconductor substrate.

7. The display device of claim 1, wherein the second single crystal semiconductor substrate is in the non-display area, and includes a plurality of third through holes in which a third conductive via connected to a plurality of second scan lines extending in the second direction is located, and
wherein the connection line layer comprises a third connection line connecting the third conductive via to an emission driver on the first single crystal semiconductor substrate.

8. The display device of claim 1, wherein a number of the first through holes is equal to a number of the data lines, and a number of pixel columns of the plurality of sub-pixels.

9. The display device of claim 1, wherein a number of the second through holes is equal to a number of the first scan lines, and is greater than a number of pixel rows of the plurality of sub-pixels.

10. The display device of claim 1, further comprising a plurality of signal terminals on the first single crystal semiconductor substrate,
wherein the second single crystal semiconductor substrate further includes a plurality of fourth through holes formed in the non-display area, and
wherein the connection line layer further comprises a fourth connection line connecting the signal terminal to a fourth conductive via in the fourth through hole.

11. The display device of claim 1, wherein an area of the first single crystal semiconductor substrate in a plan view is smaller than an area of the second single crystal semiconductor substrate in a plan view.

12. The display device of claim 1, wherein a length of a minimum line width of the first transistor is smaller than a length of a minimum line width of the second transistor.

13. The display device of claim 12, wherein the minimum line width of the first transistor is less than 100 nm, and
wherein the minimum line width of the second transistor is greater than or equal to 100 nm.

14. The display device of claim 1, further comprising a passivation layer around the first single crystal semiconductor substrate and overlapping the second single crystal semiconductor substrate.

15. A method for fabrication of a display device, comprising:
preparing a first wafer substrate and a second wafer substrate different from each other;
forming a plurality of first transistors on the first wafer substrate, forming a pixel circuit on one surface of the second wafer substrate, and forming a plurality of through holes penetrating at least a part of the second wafer substrate and a plurality of conductive vias respectively located in the plurality of through holes;
forming a connection line layer comprising a plurality of connection lines on an other surface of the second wafer substrate, which is opposite to the one surface;
dividing the first wafer substrate into a plurality of first single crystal semiconductor substrates, and locating the first single crystal semiconductor substrate on the other surface of the second wafer substrate;
forming a planarization layer covering the one surface of the second wafer substrate and the first single crystal semiconductor substrates attached to the one surface;
forming a display element layer comprising a plurality of light emitting elements on the other surface of the second wafer substrate, which is opposite to the one surface; and
dividing the second wafer substrate into a plurality of second single crystal semiconductor substrates in which the display element layer is formed on the one surface and the first single crystal semiconductor substrate is on the other surface,
wherein the plurality of through holes includes a plurality of first through holes in a non-display area around the display area and having a first conductive via therein, and a plurality of second through holes in the non-display area and having a second conductive via therein, and
wherein the connection line layer comprises a first connection line connecting the first conductive via and a data driver on the first single crystal semiconductor substrate, and a second connection line connecting the second conductive via to a scan driver on the first single crystal semiconductor substrate.

16. The method of claim 15, further comprising, after the forming of the plurality of through holes and the plurality of conductive vias, performing etching to reduce a thickness of the second wafer substrate,
wherein the first single crystal semiconductor substrate is attached to the connection line layer.

17. The method of claim 15, wherein each of the plurality of first through holes and the plurality of second through holes does not overlap the first single crystal semiconductor substrate.

18. The method of claim 15, wherein an area of the first single crystal semiconductor substrate in a plan view is smaller than an area of the second single crystal semiconductor substrate in a plan view.

19. The method of claim 15, wherein in the forming of the pixel circuit on the second wafer substrate, a plurality of second transistors are formed on the second wafer substrate, and
a length of a minimum line width of the first transistor is smaller than a length of a minimum line width of the second transistor.

20. A head mounted display device comprising:
a frame configured to be mounted on a user's body and corresponding to left and right eyes;
a plurality of display devices in the frame; and
a lens on each of the plurality of display devices,
wherein a display device from among the plurality of display devices comprises:
a first single crystal semiconductor substrate at which a plurality of first transistors are located;
a second single crystal semiconductor substrate on the first single crystal semiconductor substrate, and at which a plurality of second transistors is located; and
a connection line layer between the first single crystal semiconductor substrate and the second single crystal semiconductor substrate,
wherein the second single crystal semiconductor substrate includes a display area where a plurality of sub-pixels is located, each of the plurality of sub-pixels comprising a light emitting element, a plurality of first through holes in a non-display area around the display area, and in which a first conductive via connected to a plurality of data lines extending in a first direction is located, and a plurality of second through holes in the non-display area, and in which a second conductive via connected to a plurality of first scan lines extending in a second direction is located, and
wherein the connection line layer comprises a first connection line connecting the first conductive via to a data driver on the first single crystal semiconductor substrate, and a second connection line connecting the second conductive via to a scan driver on the first single crystal semiconductor substrate.
